(19) United States
(12) Patent Application Publication
(10) Pub. No.: US 2025/0359261 A1
(43) Pub. Date: Nov. 20, 2025

(54) SEMICONDUCTOR DEVICE

(71) Applicant: SAMSUNG ELECTRONICS CO., LTD., SUWON-SI (KR)

(72) Inventors: Seungmin CHA, Suwon-si (KR); Minchan GWAK, Suwon-si (KR); Kyoungwoo LEE, Suwon-si (KR)

(21) Appl. No.: 19/013,435

(22) Filed: Jan. 8, 2025

(30) Foreign Application Priority Data
May 14, 2024 (KR) 10-2024-0063409

(51) Int. Cl. H10D 64/23; H01L 23/528; H10D 64/62; H10D 84/01; H10D 84/85

(52) U.S. Cl. CPC H10D 64/258; H10D 64/2565; H10D 64/62; H10D 84/0153; H10D 84/851; H01L 23/5286

(57) ABSTRACT

Provided is a semiconductor device including a substrate, a lower power line disposed under the substrate, a source/drain pattern on the substrate, a channel pattern, on side surfaces of the source/drain pattern, including a plurality of semiconductor patterns stacked on each other, a gate electrode between the plurality of semiconductor patterns, a backside active contact penetrating the substrate to electrically connect the lower power line and the source/drain pattern, and a backside isolation structure penetrating the substrate and the backside active contact, and disposed under the gate electrode. An uppermost surface of the backside active contact is located at a higher level than an uppermost surface of the backside isolation structure.

### CROSS-REFERENCE TO RELATED APPLICATION

This application claims priority under 35 U.S.C. § 119 to Korean Patent Application No. 10-2024-0063409, filed on May 14, 2024, in the Korean Intellectual Property Office, the entire contents of which are hereby incorporated by reference.

### BACKGROUND

### 1. Technical Field

The present disclosure herein relates to a semiconductor device, and more particularly, to a semiconductor device including a field effect transistor.

### 2. Discussion of Related Art

A semiconductor device may include an integrated circuit composed of a metal-oxide-semiconductor field effect transistor (MOSFET). The metal-oxide-semiconductor field effect transistor may be scaled-down with a reduction in a size and a design rule of the semiconductor device. As the metal-oxide-semiconductor field effect transistor is scaled down, operational characteristics of the semiconductor device may be deteriorated.

### SUMMARY

The present disclosure provides a semiconductor device with improved electrical characteristics.

A technical goal of the inventive concept is not limited to aspects described herein, and other technical goals that are not mentioned may be clearly understood from description below by those skilled in the art.

An embodiment of the inventive concept provides a semiconductor device including a substrate, a lower power line disposed under the substrate, a source/drain pattern on the substrate, a channel pattern, on side surfaces of the source/drain pattern, including a plurality of semiconductor patterns stacked on each other, a gate electrode between the plurality of semiconductor patterns, a backside active contact penetrating the substrate to electrically connect the lower power line and the source/drain pattern, and a backside isolation structure penetrating the substrate and the backside active contact, and disposed under the gate electrode, wherein an uppermost surface of the backside active contact is located at a higher level than an uppermost surface of the backside isolation structure.

In an embodiment of the inventive concept, a semiconductor device includes a substrate, a plurality of semiconductor patterns, on the substrate, horizontally spaced apart from each other, source/drain patterns including a first pattern and a second pattern respectively interposed between the plurality of semiconductor patterns, a gate electrode between the substrate and each of the plurality of semiconductor patterns, a gate insulating film surrounding the gate electrode, a backside active contact provided under the substrate, and including a third pattern electrically connected to the first pattern and a fourth pattern separated from the second pattern, and backside isolation structures penetrating the substrate and the backside active contact, wherein the backside isolation structures include a first backside isolation structure, a second backside isolation structure, and a third backside isolation structure horizontally spaced apart from each other, and the third pattern is disposed between the first backside isolation structure and the second backside isolation structure, and the fourth pattern is disposed between the second backside isolation structure and the third backside isolation structure.

In an embodiment of the inventive concept, a semiconductor device includes a substrate including an active pattern, a device isolation film on the substrate and defining the active pattern, a channel pattern and source/drain patterns on the active pattern, the source/drain patterns including a first source/drain pattern and a second source/drain pattern horizontally spaced apart from each other, a gate electrode on the channel pattern, a gate insulating film interposed between the gate electrode and the channel pattern, a gate spacer on sidewalls of the gate electrode, a gate capping pattern on an upper surface of the gate electrode, an interlayer insulating film covering the source/drain patterns and the gate capping pattern, an upper active contact penetrating the interlayer insulating film to be electrically connected to the first source/drain pattern, a metal-semiconductor compound layer interposed between the upper active contact and the first source/drain pattern, a gate contact penetrating the interlayer insulating film and the gate capping pattern to be electrically connected to the gate electrode, a lower power line provided under the substrate, a backside active contact penetrating the substrate to electrically connect the lower power line and the second source/drain pattern, and a backside isolation structure penetrating the substrate and the backside active contact, and disposed on the gate insulating film, wherein a bottom surface of the backside isolation structure is coplanar with a bottom surface of the backside active contact and an upper surface of the lower power line, and an upper surface of the backside isolation structure is in contact with a bottom surface of the gate insulating film.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIGS. 1, 2, and 3 are conceptual views for describing logic cells of a semiconductor device according to embodiments of the inventive concept;

FIGS. 4A and 4B are plan views for describing a semiconductor device according to embodiments of the inventive concept;

FIGS. 5A to 5D are respectively cross-sectional views taken along line A-A′, line B-B′, line C-C′, and line D-D′ of FIG. 4A;

FIG. 6 is an enlarged view illustrating region M of FIG. 5A;

FIG. 7 is a cross-sectional view for describing a semiconductor device according to another embodiment of FIG. 5A; and

FIGS. 8A and 8B, FIGS. 9A and 9B, FIGS. 10A to 10C, FIGS. 11A to 11C, FIGS. 12A to 12C, FIGS. 13A to 13D, FIGS. 14A to 14D, FIGS. 15A to 15D, FIGS. 16A to 16D, and FIGS. 17A to 17D are diagrams illustrating a method for manufacturing a semiconductor device according to some embodiments of the inventive concept.

### DETAILED DESCRIPTION

Hereinafter, embodiments according to the inventive concept will be described in more detail with reference to the accompanying drawings in order to more specifically describe the inventive concept. The inventive concept may be implemented in various modifications and have various forms, and specific embodiments are illustrated in the drawings and described in detail in the text. It is to be understood, however, that the inventive concept is not intended to be limited to the particular forms disclosed, but on the contrary, is intended to cover all modifications, equivalents, and alternatives falling within the spirit and scope of the inventive concept.

The same reference numerals may refer to the same elements throughout the specification. In the drawings, the thickness, the ratio, and the dimension of the elements may be exaggerated for effective description of the technical contents.

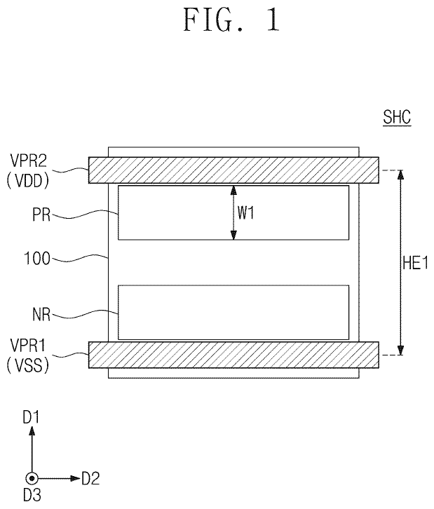

FIGS. 1, 2, and 3 are conceptual views for describing logic cells of a semiconductor device according to embodiments of the inventive concept.

Referring to FIG. 1, a single height cell SHC may be provided. Specifically, a first lower power line VPR1 and a second lower power line VPR2 may be disposed under a substrate 100. The first lower power line VPR1 may be a path through which a source voltage VSS, for example, a ground voltage may be provided. The second lower power line VPR2 may be a path through which a drain voltage VDD, for example, a power voltage may be provided.

The single height cell SHC may be defined between the first lower power line VPR1 and the second lower power line VPR2. The single height cell SHC may include a PMOSFET region PR and an NMOSFET region NR. In other words, the single height cell SHC may have a structure in which a CMOS may be provided between the first lower power line VPR1 and the second lower power line VPR2.

The PMOSFET region PR and the NMOSFET region NR may each have a first width in a first horizontal direction (that is, a first direction D1). A length of the single height cell SHC in the first direction D1 may be defined as a first height HE1. The first height HE1 may be substantially the same as a distance (for example, a pitch) between the first lower power line VPR1 and the second lower power line VPR2.

The single height cell SHC may constitute a logic cell. In the present specification, the logic cell may be a logic device (for example, AND, OR, XOR, XNOR, or an inverter) that performs a specific function. That is, the logic cell may include transistors for constituting the logic device, and lines connecting the transistors each other.

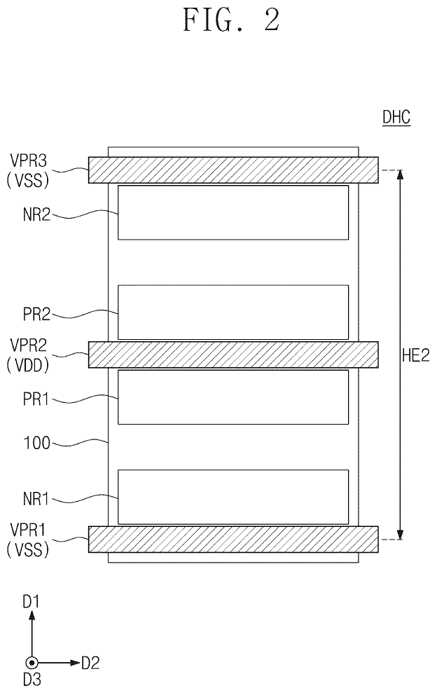

Referring to FIG. 2, a double height cell DHC may be provided. Specifically, the first lower power line VPR1, the second lower power line VPR2, and a third lower power line VPR3 may be provided on the substrate 100. The second lower power line VPR2 may be disposed between the first lower power line VPR1 and the third lower power line VPR3. The third lower power line VPR3 may be a path through which the source voltage VSS may be provided.

The double height cell DHC may be defined between the first lower power line VPR1 and the third lower power line VPR3. The double height cell DHC may include a first PMOSFET region PR1, a second PMOSFET region PR2, a first NMOSFET region NR1, and a second NMOSFET region NR2.

The first NMOSFET region NR1 may be adjacent to the first lower power line VPR1. The second NMOSFET region NR2 may be adjacent to the third lower power line VPR3. First and second PMOSFET regions PR1 and PR2 may be adjacent to the second lower power line VPR2. In a plan view, the second lower power line VPR2 may be disposed between the first and second PMOSFET regions PR1 and PR2.

A length of the double height cell DHC in the first direction D1 may be defined as a second height HE2. The second height HE2 may be about twice longer than the first height HE1 of FIG. 1. The first and second PMOSFET regions PR1 and PR2 of the double height cell DHC may operate together as a PMOSFET region. Accordingly, a channel size of a PMOS transistor of the double height cell DHC may be greater than a channel size of the PMOS transistor of the single height cell SHC of FIG. 1.

For example, the channel size of the PMOS transistor of the double height cell DHC may be about twice longer than the channel size of the PMOS transistor of the single height cell SHC. As a result, the double height cell DHC may operate faster than the single height cell SHC. According to an embodiment of the inventive concept, the double height cell DHC illustrated in FIG. 2 may be defined as a multi-height cell. Although not shown, the multi-height cell may include a triple height cell of which a cell height may be about three times longer than that of the single height cell SHC.

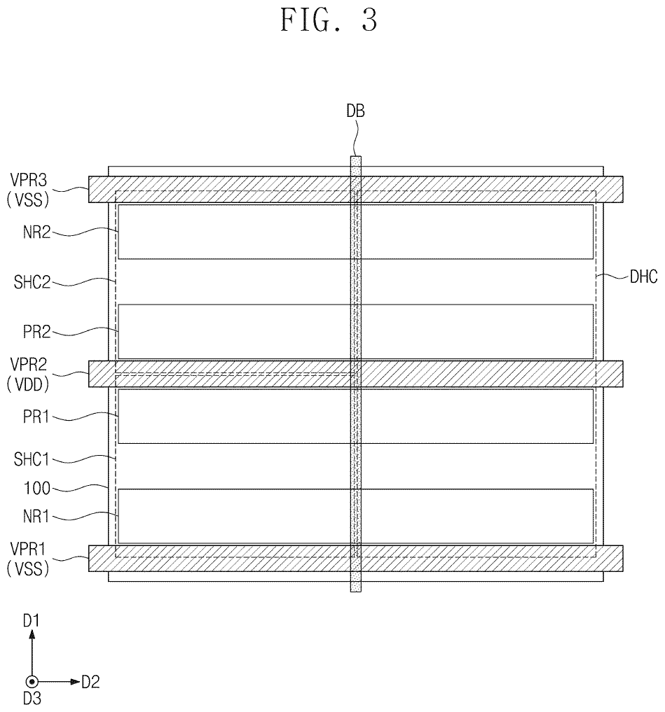

Referring to FIG. 3, a first single height cell SHC1, a second single height cell SHC2, and the double height cell DHC may be two-dimensionally disposed on the substrate 100. The first single height cell SHC1 may be disposed between the first and second lower power lines VPR1 and VPR2. The second single height cell SHC2 may be disposed between the second and third lower power lines VPR2 and VPR3. The second single height cell SHC2 may be adjacent to the first single height cell SHC1 in the first direction D1.

The double height cell DHC may be disposed between the first and third lower power lines VPR1 and VPR3. The double height cell DHC may be adjacent to the first and second single height cells SHC1 and SHC2 in a second horizontal direction (that is, a second direction D2 crossing the first direction D1).

An isolation structure DB may be provided between the first single height cell SHC1 and the double height cell DHC, and between the second single height cell SHC2 and the double height cell DHC. An active region of the double height cell DHC may be electrically isolated from an active region of each of the first and second single height cells SHC1 and SHC2 by the isolation structure DB.

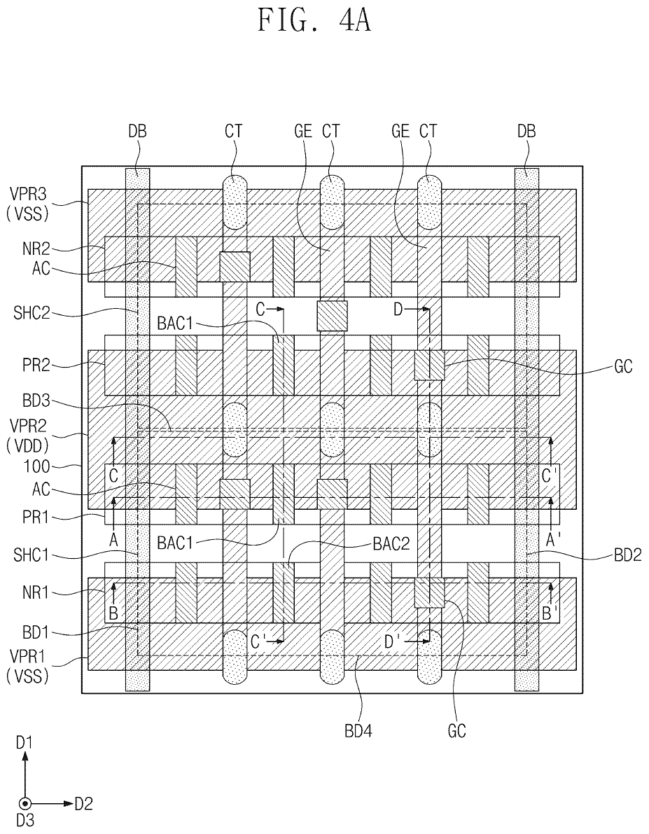

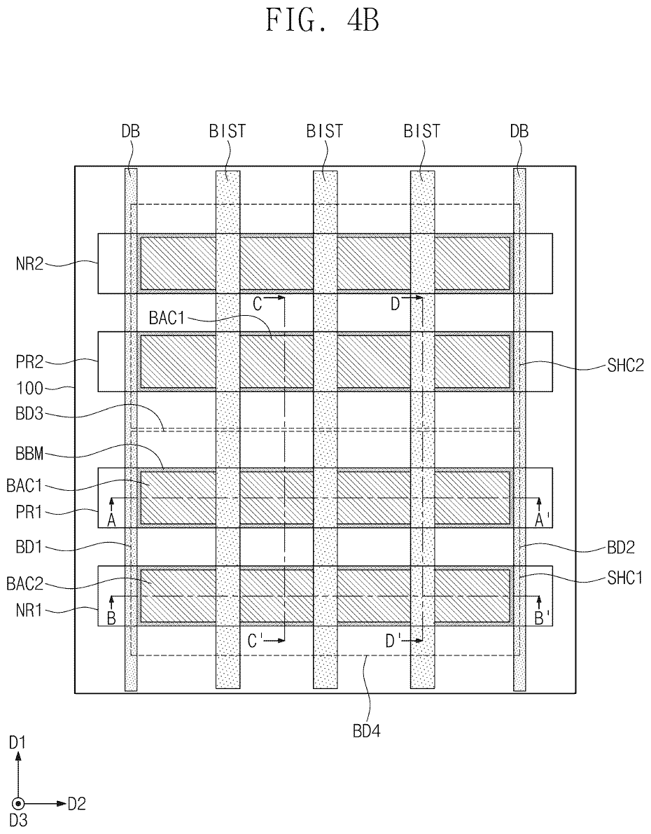

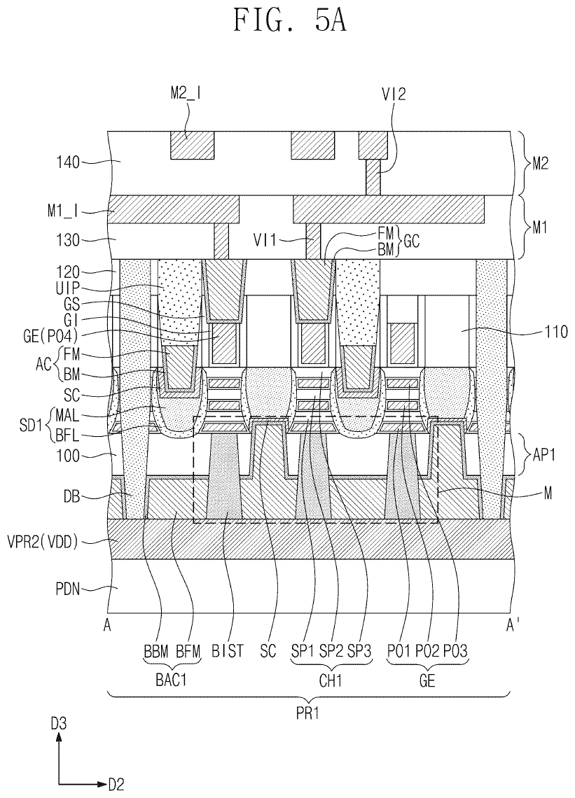

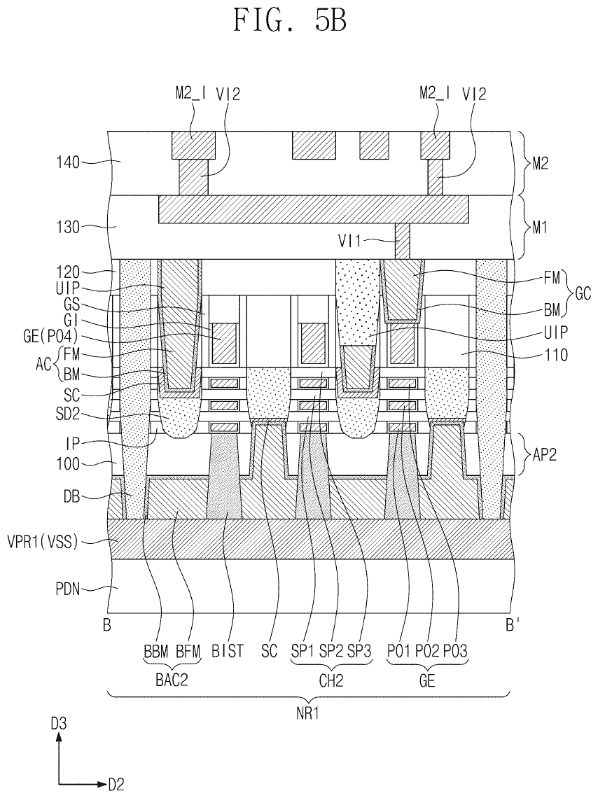

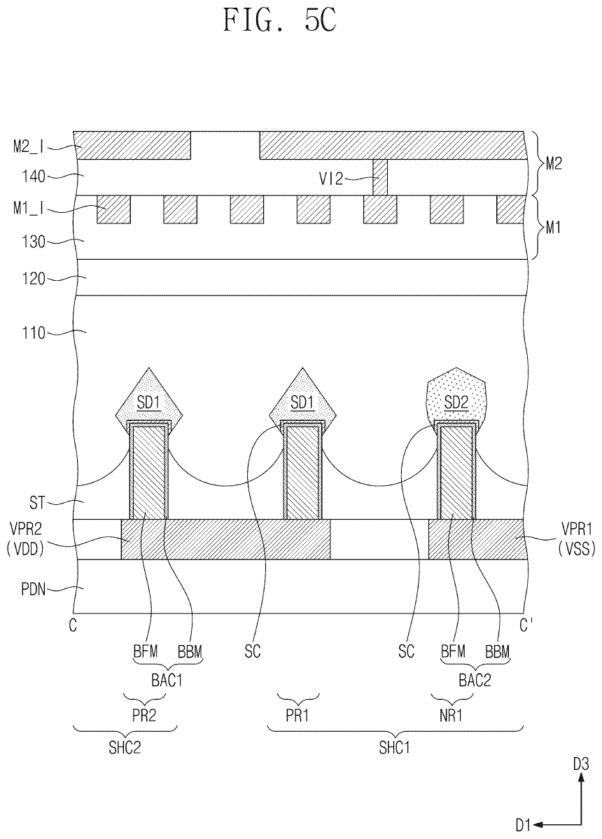

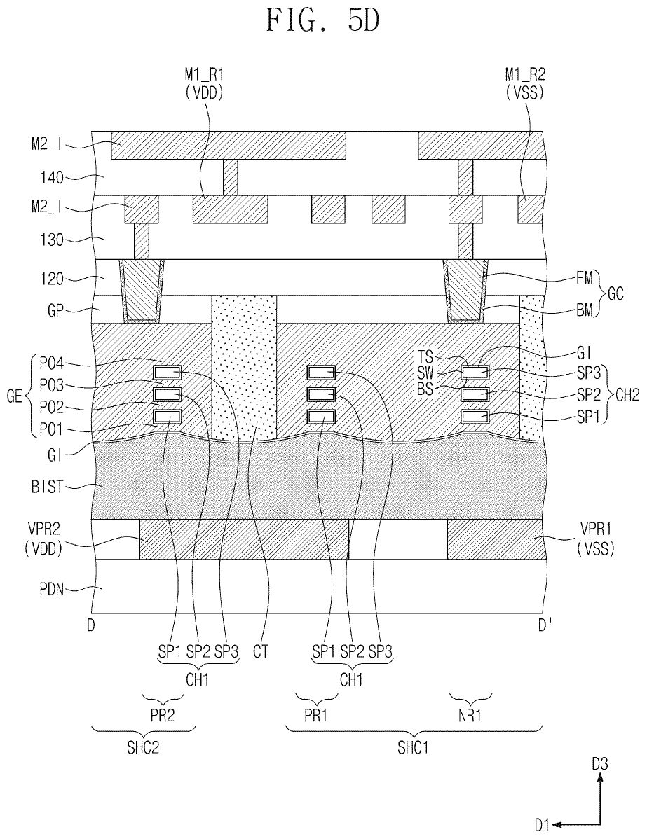

FIGS. 4A and 4B are plan views for describing a semiconductor device according to embodiments of the inventive concept. FIG. 4A is a front surface plan view from a front surface of the semiconductor device, and FIG. 4B is a backside plan view from a backside of the semiconductor device. FIGS. 5A to 5D are respectively cross-sectional views taken along line A-A′, line B-B′, line C-C′, and line D-D′ of FIG. 4A. In the semiconductor device illustrated in FIGS. 4A and 4B, and FIGS. 5A to 5D, the first and second single height cells SHC1 and SHC2 of FIG. 3 are more specifically illustrated.

Referring to FIG. 4A, and FIGS. 5A to 5D, the first and second single height cells SHC1 and SHC2 may be provided on the substrate 100. Logic transistors that constitute a logic circuit may be disposed on each of the first and second single height cells SHC1 and SHC2. The substrate 100 may be a semiconductor substrate including silicon, germanium, silicon-germanium, or the like, or a compound semiconductor substrate. For example, the substrate 100 may be a silicon substrate. As another example, the substrate 100 may include a silicon-based insulating layer, and may include a silicon oxide film, a silicon nitride film, or a silicon oxynitride film. Lower power lines VPR1, VPR2, and VPR3 described herein may be disposed under the substrate 100.

The substrate 100 may have the first PMOSFET region PR1, the second PMOSFET region PR2, the first NMOSFET region NR1, and the second NMOSFET region NR2. The first PMOSFET region PR1, the second PMOSFET region PR2, the first NMOSFET region NR1, and the second NMOSFET region NR2 may each extend in the second direction D2. The first single height cell SHC1 may include the first NMOSFET region NR1 and the first PMOSFET region PR1, and the second single height cell SHC2 may include the second PMOSFET region PR2 and the second NMOSFET region NR2.

A first active pattern AP1 and a second active pattern AP2 may be defined by a trench TR formed on the substrate 100. The first active pattern AP1 may be provided on each of the first and second PMOSFET regions PR1 and PR2. The second active pattern AP2 may be provided on each of the first and second NMOSFET regions NR1 and NR2. The first and second active patterns AP1 and AP2 may extend in the second direction D2. The first and second active patterns AP1 and AP2 may be vertical protrusions as parts of the substrate 100.

A device isolation film ST may fill the trench TR. The device isolation film ST may cover sidewalls of each of the first and second active patterns AP1 and AP2. The device isolation film ST may include a silicon oxide film. The device isolation film ST may not cover first and second channel patterns CH1 and CH2 described herein.

A first channel pattern CH1 may be provided on the first active pattern AP1. A second channel pattern CH2 may be provided on the second active pattern AP2. Each of the first channel pattern CH1 and the second channel pattern CH2 may include a first semiconductor pattern SP1, a second semiconductor pattern SP2, and a third semiconductor pattern SP3 sequentially stacked. The first to third semiconductor patterns SP1, SP2, and SP3 may be spaced apart from each other in a vertical direction (that is, a third direction D3).

The first to third semiconductor patterns SP1, SP2, and SP3 may each include silicon (Si), germanium (Ge), or silicon-germanium (SiGe). For example, the first to third semiconductor patterns SP1, SP2, and SP3 may each include crystalline silicon. The first to third semiconductor patterns SP1, SP2, and SP3 may be each a nanosheet.

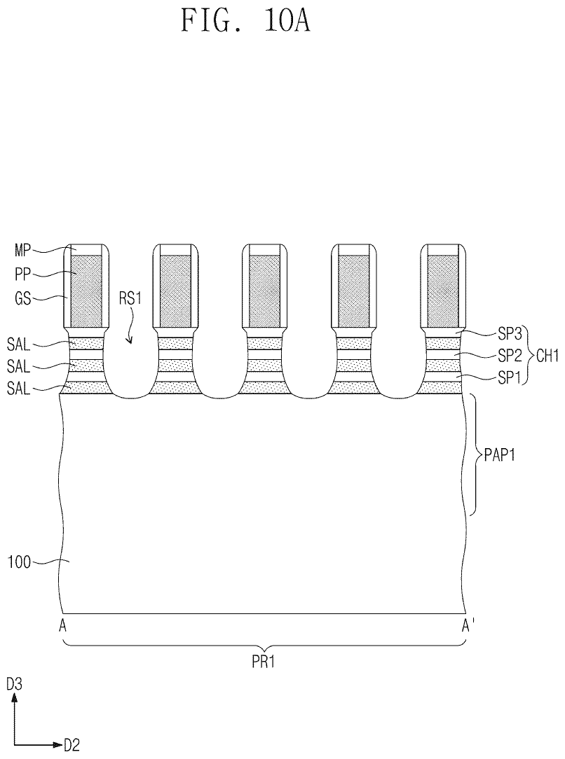

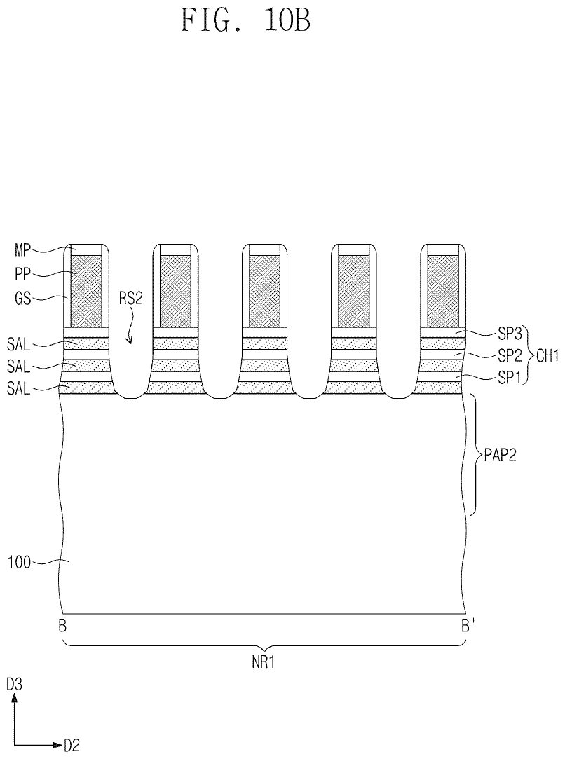

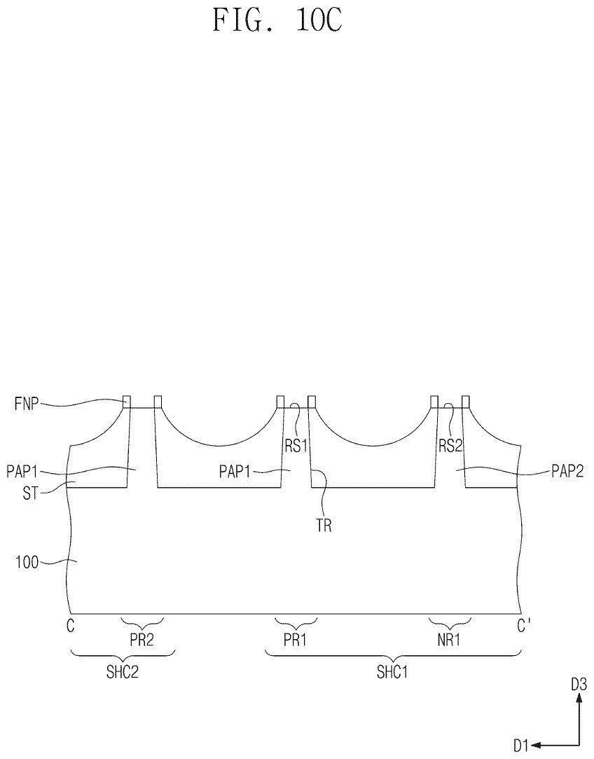

A plurality of first source/drain patterns SD1 may be provided on the first active pattern AP1. A plurality of first recesses RS1 may be formed on the first active pattern AP1. The first source/drain patterns SD1 may be respectively provided in the first recesses RS1 (see FIG. 10A). The first source/drain patterns SD1 may be impurity regions having a first conductive type (for example, a P-type). The first channel pattern CH1 may be interposed between a pair of first source/drain patterns SD1. In other words, the stacked first to third semiconductor patterns SP1, SP2, and SP3 may connect the pair of first source/drain patterns SD1 each other.

A plurality of second source/drain patterns SD2 may be provided on the second active pattern AP2. A plurality of second recesses RS2 (see FIG. 10B) may be formed on the second active pattern AP2. The second source/drain patterns SD2 may be respectively provided in the second recesses RS2. The second source/drain patterns SD2 may be impurity regions having a second conductive type (for example, an N-type). The second channel pattern CH2 may be interposed between a pair of second source/drain patterns SD2. In other words, the stacked first to third semiconductor patterns SP1, SP2, and SP3 may connect the pair of second source/drain patterns SD2 each other.

The first and second source/drain patterns SD1 and SD2 may be epitaxial patterns formed in a selective epitaxial growth (SEG) process. For example, an upper surface of each of the first and second source/drain patterns SD1 and SD2 may be located at substantially the same level as an upper surface of the third semiconductor pattern SP3. As another example, the upper surface of each of the first and second source/drain patterns SD1 and SD2 may be located at a higher level than the upper surface of the third semiconductor pattern SP3.

The first source/drain patterns SD1 may include a semiconductor element (for example, SiGe) having a greater lattice parameter than a semiconductor element of the first channel pattern CH1. Accordingly, the pair of the first source/drain patterns SD1 may supply a compressive stress to the first channel pattern CH1 therebetween. The second source/drain patterns SD2 may include the same semiconductor element (for example, Si) as the second channel pattern CH2.

Each of the first source/drain patterns SD1 may include a buffer layer BFL, and a main layer MAL on the buffer layer BFL. Referring to FIG. 5A, the buffer layer BFL may be disposed on at least a portion of an inner sidewall of the first recess RS1. The buffer layer BFL may cover an inner sidewall of the first recess RS1. The main layer MAL may be disposed on the buffer layer BFL in a region of the first recess RS1. The main layer MAL may fill the remaining region of the first recess RS1 formed following a formation of the buffer layer BFL. The main layer MAL may have a greater volume than the buffer layer BFL. The main layer MAL and the buffer layer BFL may each include silicon-germanium (SiGe). Specifically, the buffer layer BFL may contain germanium (Ge) at a relatively low concentration. According to another embodiment of the inventive concept, the buffer layer BFL may contain silicon (Si), and may not include germanium (Ge). The buffer layer BFL may have germanium (Ge) at a concentration of 0 at % to about 30 at %.

The main layer MAL may contain germanium (Ge) at a relatively high concentration. For example, the main layer MAL may have germanium (Ge) at a concentration of about 30 at % to about 70 at %. A germanium (Ge) concentration of the main layer MAL may increase in a third direction D3. For example, the main layer MAL adjacent to the buffer layer BFL may have germanium (Ge) at a concentration of about 40 at %, but an upper part of the main layer MAL may have germanium (Ge) at a concentration of about 60 at %.

Each of the buffer layer BFL and the main layer MAL may include impurities (for example, boron, gallium, or indium), which may cause the first source/drain pattern SD1 to be the P-type. The buffer layer BFL and the main layer MAL may each have an impurity concentration of about 1E18 atom/cm³ to about 5E22 atom/cm³. The main layer MAL may have a greater impurity concentration than the buffer layer BFL.

While second semiconductor layers SAL described herein are substituted to first inner electrode PO1, second inner electrodes PO2, and third inner electrode PO3 of a gate electrode GE, the buffer layer BFL may protect the main layer MAL. In other words, the buffer layer BFL may prevent an etching material that removes the second semiconductor layers SAL from infiltrating into and etching the main layer MAL.

The second source/drain patterns SD2 may each include silicon (Si). The second source/drain patterns SD2 may further include impurities (for example, phosphorus, arsenic, or antimony), which may cause the second source/drain pattern SD2 to be the N-type. The second source/drain pattern SD2 may have an impurity concentration of about 1E18 atom/cm³ to about 5E22 atom/cm³.

The gate electrodes GE crossing the first and second channel patterns CH1 and CH2 and extending in the first direction D1 may be provided. The gate electrodes GE may be spaced apart from each other and arranged with a first pitch in the second direction D2. The gate electrodes GE may respectively vertically overlap the first and second channel patterns CH1 and CH2 in the third direction D3.

The gate electrode GE may include a first inner electrode PO1 interposed between the active pattern AP1 or AP2 and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3. While the gate electrode GE is illustrated as having four electrodes, embodiments are not limited thereto. For example, the gate electrode GE may include less than four or more than four electrodes.

Referring to FIG. 5D, the gate electrode GE may be provided on an upper surface TS, a bottom surface BS, and both sidewalls SW of each of the first to third semiconductor patterns SP1, SP2, and SP3. In other words, a transistor according to an embodiment may be a three-dimensional field effect transistor (for example, a MBCFET or GAAFET) in which the gate electrodes GE may surround a channel in three-dimensions.

Representatively, the first single height cell SHC1 may have a first boundary BD1 and a second boundary BD2 opposed to each other in the second direction D2. The first and second boundaries BD1 and BD2 may extend in the first direction D1. The first single height cell SHC1 may have a third boundary BD3 and a fourth boundary BD4 opposed to each other in the first direction D1. The third and fourth boundaries BD3 and BD4 may extend in the second direction D2.

Gate cutting patterns CT may be disposed on a boundary of each of the first and second single height cells SHC1 and SHC2 in the second direction D2. For example, the gate cutting patterns CT may be disposed on the third and fourth boundaries BD3 and BD4 of the first single height cell SHC1. At least some of gate cutting patterns CT may be spaced apart from each other and arranged with the first pitch along the third boundary BD3 in the second direction D2. The pitch of the gate cutting patterns CT in the second direction D2 may have the same pitch as the gate electrodes GE. Further, the gate cutting patterns CT disposed on the third boundary BD3 may also be disposed on a boundary of the second single height cell SHC2. For example, some of the gate cutting patterns may be disposed on adjacent boundaries of the first and second single height cells SHC1 and SHC2. Others of the gate cutting patterns CT may be spaced apart from each other and arranged with the first pitch along the fourth boundary BD4. In a plan view, the gate cutting patterns CT on the third and fourth boundaries BD3 and BD4 may be disposed so as to respectively overlap the gate electrodes GE. The gate cutting patterns CT may include an insulating material such as a silicon oxide film, a silicon nitride film, or a combination thereof.

The gate electrode GE on the first single height cell SHC1 and the gate electrode GE on the second single height cell SHC2 may be separated by the gate cutting pattern CT. The gate cutting pattern CT may be interposed between the gate electrode GE on the first single height cell SHC1 and the gate electrode GE on the second single height cell SHC2 aligned therewith in the first direction D1. In other words, the gate electrode GE extending in the first direction D1 may be divided to a plurality of gate electrodes GE by the gate cutting patterns CT.

Referring to FIG. 4A, and FIGS. 5A to 5D, a pair of gate spacers GS may be respectively disposed on sidewalls of the outer electrode PO4 of the gate electrode GE. The gate spacers GS may extend along the gate electrode GE in the first direction D1. The gate spacers GS may have higher upper surfaces than the gate electrode GE. The upper surfaces of the gate spacers GS may be coplanar with an upper surface of a first interlayer insulating film 110 described herein. The gate spacers GS may include at least one of SiCN, SiCON, or SiN. As another example, the gate spacers GS may include a multi-layered film composed of at least two of SiCN, SiCON, or SiN.

A gate capping pattern GP may be provided on the gate electrode GE. The gate capping pattern GP may extend along the gate electrode GE in the first direction D1. The gate capping pattern GP may include a material having etching selectivity with respect to the first interlayer insulating film 110 and the second interlayer insulating film 120 described herein. Specifically, the gate capping pattern GP may include at least one of SiON, SiCN, SiCON, or SiN.

A gate insulating film GI may be interposed between the gate electrode GE and the first channel pattern CH1, and between the gate electrode GE and the second channel pattern CH2. The gate insulating film GI may cover the upper surface TS, the bottom surface BS, and the both sidewalls SW of each of the first to third semiconductor patterns SP1, SP2, and SP3. The gate insulating film GI may cover an upper surface of the device isolation film ST under the gate electrodes GE. The gate insulating film GI may cover an upper surface of a backside isolation structure BIST under the gate electrode GE (see FIG. 5D). The gate insulating film GI may be interposed between the first inner electrode PO1 and the backside isolation structure BIST.

According to an embodiment of the inventive concept, the gate insulating film GI may include a silicon oxide film, a silicon oxynitride film, and/or a high dielectric film. The high dielectric film may include a material having a higher dielectric constant than the silicon oxide film. For example, the material having a higher dielectric constant than the silicon oxide film may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The gate electrode GE may include a first metal pattern, and a second metal pattern on the first metal pattern. The first metal pattern may be provided on the gate insulating film GI to be adjacent to the first to third semiconductor patterns SP1, SP2, and SP3. The first metal pattern may include work-function metal that controls a threshold voltage of a transistor. A targeted threshold voltage of the transistor may be achieved by controlling a thickness and a composition of the first metal pattern. For example, the first to third inner electrodes PO1, PO2, and PO3 of the gate electrode GE may be composed of the first metal pattern composed of the work-function metal.

The first metal pattern may include a metal nitride film. For example, the first metal pattern may include nitrogen (N) and at least one metal selected from the group consisting of titanium (Ti), tantalum (Ta), aluminum (Al), tungsten (W), or molybdenum (Mo), or a combination thereof. Moreover, the first metal pattern may further include carbon (C). The first metal pattern may include a plurality of stacked work-function metal films.

The second metal pattern may include metal having a lower resistance than that of the first metal pattern. For example, the second metal pattern may include at least one metal selected from the group consisting of titanium (Ti), tantalum (Ta), aluminum (Al), or tungsten (W), or a combination thereof. For example, the outer electrode PO4 of the gate electrode GE may include the first metal pattern and the second metal pattern on the first metal pattern.

Referring to FIG. 5B, inner spacers IP may be provided on the first and second NMOSFET regions NR1 and NR2. In other words, the inner spacers IP may be provided on the second active pattern AP2. The inner spacers IP may be respectively interposed between the second source/drain patterns SD2 and the first to third inner electrodes PO1, PO2, and PO3 of the gate electrode GE. The inner spacers IP may be in direct contact with the second source/drain patterns SD2. Each of the first to third inner electrodes PO1, PO2, and PO3 of the gate electrodes GE may be spaced apart from the second source/drain patterns SD2 by the inner spacers IP.

The first interlayer insulating film 110 may be provided on the substrate 100. The first interlayer insulating film 110 may cover the gate spacers GS and the first and second source/drain patterns SD1 and SD2. An upper surface of the first interlayer insulating film 110 may be substantially coplanar with an upper surface of the gate capping pattern GP and an upper surface of the gate spacer GS. The second interlayer insulating film 120 covering the gate capping pattern GP may be disposed on the first interlayer insulating film 110. A third interlayer insulating film 130 may be provided on the second interlayer insulating film 120. A fourth interlayer insulating film 140 may be provided on the third interlayer insulating film 130. For example, the first interlayer insulating film 110, the second interlayer insulating film 120, the third interlayer insulating film 130, and the fourth interlayer insulating film 140 may each include a silicon oxide film.

A pair of isolation structures DB opposed to each other in the second direction D2 may be provided on both sides of each of the first and second single height cells SHC1 and SHC2. For example, the pair of isolation structures DB may be respectively provided on the first and second boundaries BD1 and BD2 of the first single height cell SHC1. The isolation structure DB may extend parallel to the gate electrodes GE in the first direction D1. A pitch between the isolation structure DB and the gate electrodes GE adjacent thereto may be the same as the first pitch.

The isolation structure DB may penetrate the gate capping pattern GP and the gate electrodes GE to extend to the insides of the first and second active patterns AP1 and AP2. The isolation structure DB may penetrate an upper part of each of the first and second active patterns AP1 and AP2. The isolation structure DB may electrically isolate an active region of each of the first and second single height cells SHC1 and SHC2 from an active region of another cell adjacent thereto.

Upper active contacts AC penetrating the first interlayer insulating film 110 and the second interlayer insulating film 120 to be respectively electrically connected to the first source/drain pattern SD1 and the second source/drain pattern SD2 may be provided. Each of the upper active contacts AC may be provided so as to be adjacent to a side of the gate electrodes GE. In a plan view, the upper active contact AC may have a form of a bar extending in the first direction D1.

The upper active contact AC may be a self-aligned contact. In other words, the upper active contact AC may be formed self-aligned using the gate capping pattern GP and the gate spacer GS. For example, the upper active contact AC may at least partially cover sidewalls of the gate spacer GS. Although not shown, the upper active contact AC may partially cover an upper surface of the gate capping pattern GP.

A metal-semiconductor compound layer SC, for example, a silicide layer may be respectively interposed between the upper active contact AC and the first source/drain pattern SD1, and between the upper active contact AC and the second source/drain pattern SD2. The upper active contact AC may be electrically connected to the source/drain patterns SD1 and SD2 through the metal-semiconductor compound layer SC. For example, the metal-semiconductor compound layer SC may include at least one of titanium-silicide, tantalum-silicide, tungsten-silicide, nickel-silicide, or cobalt-silicide.

Gate contacts GC penetrating the second interlayer insulating film 120 and the gate capping pattern GP to be respectively electrically connected to the gate electrodes GE may be provided. In a plan view, two gate contacts GC on the first single height cell SHC1 may be disposed so as to overlap the first PMOSFET region PR1. In other words, the two gate contacts GC on the first single height cell SHC1 may be provided on the first active pattern AP1 (see FIG. 5A). In a plan view, a gate contact GC on the first single height cell SHC1 may be disposed so as to overlap the first NMOSFET region NR1. In other words, the gate contact GC on the first single height cell SHC1 may be provided on the second active pattern AP2 (see FIG. 5B).

The gate contact GC may be freely disposed on the gate electrode GE without limitation of a position. For example, the gate contacts GC on the second single height cell SHC2 may be respectively disposed on the second PMOSFET region PR2, the second NMOSFET region NR2, and the device isolation film ST that fills the trench TR (see FIG. 4A).

According to an embodiment of the inventive concept, referring to FIGS. 5A and 5B, the gate contact GC may be in direct contact with an upper surface of the outer electrode PO4. The gate contact GC may be in direct contact with an upper surface of the outer electrode PO4 and an upper surface of a portion of gate insulating film GI disposed on surfaces of the outer electrode PO4 of the gate electrode GE. For example, the gate insulating film GI may be disposed on sides surfaces of the outer electrode PO4 and between the third semiconductor pattern SP3. The gate insulating film GI may expose the upper surface of the outer electrode PO4. An upper part of the upper active contact AC adjacent to the gate contact GC may be filled with an upper insulating pattern UIP. The upper insulating pattern UIP may have a lower bottom surface than the gate contact GC. In other words, an upper surface of the upper active contact AC adjacent to the gate contact GC may become lower than a bottom surface of the gate contact GC due to the upper insulating pattern UIP. Accordingly, a short circuit occurring when the gate contact GC is in contact with the upper active contacts AC adjacent thereto may be prevented. For example, the upper insulating pattern UIP may include a silicon-based insulating material (for example, a silicon oxide film, a silicon nitride film, or a silicon oxynitride film).

Each of the upper active contact AC and the gate contact GC may include a conductive pattern FM and a barrier pattern BM. The barrier pattern BM may be disposed on side portions of the conductive pattern FM. For example, the barrier pattern BM may surround at least a portion of the conductive pattern FM. For example, the conductive pattern FM may include at least one metal of aluminum, copper, tungsten, molybdenum, or cobalt. The barrier pattern BM may cover sidewalls and a bottom surface of the conductive pattern FM. The barrier pattern BM may expose an upper surface of the conductive pattern FM. The barrier pattern BM may include a metal film/metal nitride film. The metal film may include at least one of titanium, tantalum, tungsten, nickel, cobalt or platinum. The metal nitride film may include at least one of titanium nitride (TiN), tantalum nitride (TaN), tungsten nitride (WN), nickel nitride (NiN), cobalt nitride (CoN), or platinum nitride (PtN).

Referring to FIG. 4A, and FIGS. 5A to 5D, the first to third lower power lines VPR1, VPR2, and VPR3 may be provided under the substrate 100. The first to third lower power lines VPR1, VPR2, and VPR3 may extend parallel to each other in the second direction D2. The first lower power line VPR1 may be disposed on the fourth boundary BD4 of the first single height cell SHC1. The second lower power line VPR2 may be disposed on the third boundary BD3 of the first single height cell SHC1. In other words, the first single height cell SHC1 may be defined between the first lower power line VPR1 and the second lower power line VPR2. The second single height cell SHC2 may be defined between the second lower power line VPR2 and the third lower power line VPR3.

According to an embodiment of the inventive concept, the first lower power line VPR1 may vertically overlap the first NMOSFET region NR1. The second lower power line VPR2 may vertically overlap the first PMOSFET region PR1 and the second PMOSFET region PR2. The third lower power line VPR3 may vertically overlap the second NMOSFET region NR2.

The first to third lower power lines VPR1, VPR2, and VPR3 may include at least one selected from the group consisting of copper, molybdenum, tungsten, or ruthenium, or a combination thereof.

A power transmission network layer PDN may be provided. The power transmission network layer PDN may be provided on a bottom surface of the substrate 100. The power transmission network layer PDN may include a plurality of lower lines electrically connected to the first to third lower power lines VPR1, VPR2, and VPR3. For example, the power transmission network layer PDN may include a line network for applying the source voltage VSS to the first and third lower power lines VPR1 and VPR3. The power transmission network layer PDN may include a line network for applying the drain voltage VDD to the second lower power line VPR2.

Referring to FIGS. 4A and 4B, and FIGS. 5A, 5B, and 5C, a first backside active contact BAC1 may be provided. The first backside active contact BAC1 may penetrate the substrate 100 and may vertically extend from the second lower power line VPR2 to the first source/drain pattern SD1. A second backside active contact BAC2 may be provided. The second backside active contact BAC2 may penetrate the substrate 100 and may vertically extend from the first lower power line VPR1 to the second source/drain pattern SD2.

Specifically, the first and second backside active contacts BAC1 and BAC2 may be disposed under the substrate 100 to have a tapered. shape. For example, a lower width of each of the first and second backside active contacts BAC1 and BAC2 may be larger than an upper width thereof. Each of the first and second backside active contacts BAC1 and BAC2 may have a shape of a bar or plate extending between a pair of isolation structures DB in the second direction D2 in a plan view.

The first backside active contact BAC1 may vertically extend to the first source/drain pattern SD1 not in contact with the upper active contact AC. The second backside active contact BAC2 may vertically extend to the second source/drain pattern SD2 not in contact with the upper active contact AC.

The first backside active contact BAC1 may have a form of a conductive column vertically and electrically connecting the second lower power line VPR2 and the first source/drain pattern SD1. The drain voltage VDD may be applied to the first source/drain pattern SD1 through the first backside active contact BAC1.

The second backside active contact BAC2 may have a form of a conductive column vertically and electrically connecting the first lower power line VPR1 and the second source/drain pattern SD2. The source voltage VSS may be applied to the second source/drain pattern SD2 through the second backside active contact BAC2.

The metal-semiconductor compound layer SC may be provided between each of the first and second backside active contacts BAC1 and BAC2 and the source/drain patterns SD1 and SD2. For example, the metal-semiconductor compound layer SC may be a silicide layer. The first and second backside active contacts BAC1 and BAC2 may be electrically connected to the first source/drain pattern SD1 or the second source/drain pattern SD2 through the metal-semiconductor compound layer SC. For example, the metal-semiconductor compound layer SC may include at least one of titanium-silicide, tantalum-silicide, tungsten-silicide, nickel-silicide, or cobalt-silicide.

The first and second backside active contacts BAC1 and BAC2 may each include a backside conductive pattern BFM and a backside barrier pattern BBM. The backside barrier pattern BBM may be disposed on the backside conductive pattern BFM. The backside barrier pattern BBM may surround at least a portion of the backside conductive pattern BFM. The backside barrier pattern BBM may cover sidewalls and an upper surface of the backside conductive pattern BFM. For example, the backside conductive pattern BFM may include at least one metal of aluminum, copper, tungsten, molybdenum, or cobalt. The backside barrier pattern BBM may cover the sidewalls and the upper surface of the backside conductive pattern BFM. The backside barrier pattern BBM may include a metal film/metal nitride film. The metal film may include at least one of titanium, tantalum, tungsten, nickel, cobalt, or platinum. The metal nitride film may include at least one of titanium nitride (TiN), tantalum nitride (TaN), tungsten nitride (WN), nickel nitride (NiN), cobalt nitride (CoN), or platinum nitride (PtN). The backside conductive pattern BFM may include the same material as the conductive pattern FM described herein, and the backside barrier pattern BBM may include the same material as the barrier pattern BM described herein.

The backside isolation structure BIST may be disposed under the gate electrode GE. For example, the backside isolation structure BIST may penetrate the substrate 100 and the first backside active contact BAC1 at a position disposed under a respective gate electrode GE. Another backside isolation structure BIST may penetrate the substrate 100 and the second backside active contact BAC2 at another position disposed under a respective electrode GE The backside isolation structure BIST may extend from an upper surface of the lower power line VPR1 or VPR2 to a bottom surface of the gate insulating film GI surrounding the first inner electrode PO1. That is, the backside isolation structure BIST may be in direct contact with the bottom surface of the gate insulating film GI. A width of at least a portion of the backside isolation structure BIST in the second direction D2 may be tapered and become smaller toward the third direction D3.

Referring to FIG. 4B, the backside active contact BAC1 or BAC2 disposed between the backside isolation structures BIST may include the backside barrier pattern BBM disposed on an upper surface or a lower surface thereof in a plan view. That is, the backside barrier pattern BBM may not be disposed on side surfaces of each of the backside isolation structures BIST. The backside active contact BAC1 or BAC2 disposed between the backside isolation structure BIST and the isolation structure DB, may include the backside barrier pattern BBM disposed on the upper surface, the lower surface, or the side surface thereof in a plan view. That is, the backside barrier pattern BBM may be disposed on a side surface of the isolation structure DB.

An uppermost surface of the backside isolation structure BIST may be located at a lower level than an uppermost surface of the backside active contact BAC1 or BAC2 in the third direction D3. That is, the uppermost surface of the backside active contact BAC1 or BAC2 may be located at a higher level than the uppermost surface of the backside isolation structure BIST in the third direction D3. A bottom surface of the backside isolation structure BIST may be substantially coplanar with a bottom surface of the backside active contact BAC1 or BAC2.

An upper part of the backside isolation structure BIST may be in contact with the substrate 100, and a lower part of the backside isolation structure BIST may be in contact with the backside active contact BAC1 or BAC2. Specifically, a first portion of the lower part of the backside isolation structure BIST may be in direct contact with the backside barrier pattern BBM of the backside active contact BAC1 or BAC2, and a second portion of the lower part of the backside isolation structure BIST may be in direct contact with the backside conductive pattern BFM of the backside active contact BAC1 or BAC2. In other words, the second portion of the lower part of the backside isolation structure BIST may be in direct contact with the backside conductive pattern BFM and may be disposed apart from the backside barrier pattern BBM of the backside active contact BAC1 or BAC2. At least because the backside active contact BAC1 or BAC2 may be formed before the backside isolation structure BIST in a manufacturing method described herein, the second portion of the lower part of the backside isolation structure BIST may be disposed without direct contact with the backside barrier pattern BBM of the backside active contact BAC1 or BAC2.

The backside isolation structure BIST may include a silicon-based insulating material (for example, a silicon oxide film, a silicon nitride film, or a silicon oxynitride film). The backside isolation structure BIST may separate the backside active contact BAC1 or BAC2 into units electrically connected to the source/drain patterns SD1 or SD2 of a transistor. That is, the backside isolation structure BIST may electrically separate the backside active contact BAC1 or BAC2 into units, which may enable the selection of individual ones of the source/drain patterns SD1 or SD2 to which the drain voltage VDD or the source voltage VSS may be applied. Hereinafter, the backside isolation structure BIST described herein.

Referring to FIG. 4A, and FIGS. 5A to 5D, a first metal layer M1 may be provided in the third interlayer insulating film 130. The first metal layer M1 may include first lines M1_I. The first lines M1_I of the first metal layer M1 may extend parallel to each other in the second direction D2.

According to embodiments of the inventive concept, a power line for supplying power to the single height cell SHC may be provided under the substrate 100. The power line may be provided in a form of the lower power lines VPR1, VPR2, and VPR3. As described herein, the lower power lines VPR1, VPR2, and VPR3 may be disposed under the substrate 100 As another example, the lower power lines VPR1, VPR2, and VPR3 may be buried in the substrate 100. Accordingly, the power line may be omitted in the first metal layer M1. The first lines M1_I for signal transmission may be disposed in the first metal layer M1.

The first metal layer M1 may further include first vias VI1. The first vias VI1 may be respectively provided under the first lines M1_I of the first metal layer M1. The upper active contact AC and the first line M1_I of the first metal layer M1 may be electrically connected to each other through the first via VI1. The gate contact GC and the first line M1_I of the first metal layer M1 may be electrically connected to each other through the first via VI1.

The first line M1_I of the first metal layer M1 and the first via VI1 thereunder may be formed in separate processes. In other words, the first line M1_I of the first metal layer M1 and the first via VI1 may be each formed in a single damascene process. The semiconductor device according to an embodiment may be formed using a process of manufacturing a semiconductor device having a design rule less than about 20 nm.

A second metal layer M2 may be provided in the fourth interlayer insulating film 140. The second metal layer M2 may include a plurality of second lines M2_I. The second lines M2_I of the second metal layer M2 may each have a form of a line or bar extending in the first direction D1. In other words, the second lines M2_I may extend parallel to each other in the first direction D1.

The second metal layer M2 may further include second vias VI2 provided under the second lines M2_I. The first line M1_I of the first metal layer M1 and the second line M2_I of the second metal layer M2 may be electrically connected to each other through the second via VI2. For example, the second line M2_I of the second metal layer M2 and the second via VI2 thereunder may be formed together in a dual damascene process.

The first line M1_I of the first metal layer M1 and the second line M2_I of the second metal layer M2 may include the same material or different materials. For example, the first line M1_I of the first metal layer M1 and the second line M2_I of the second metal layer M2 may include at least one metal material selected from aluminum, copper, tungsten, molybdenum, ruthenium, or cobalt. Although not shown, metal layers (for example, M3, M4, M5) stacked on the fourth interlayer insulating film 140 may be additionally disposed. Each of the stacked metal layers may include lines for routing between cells.

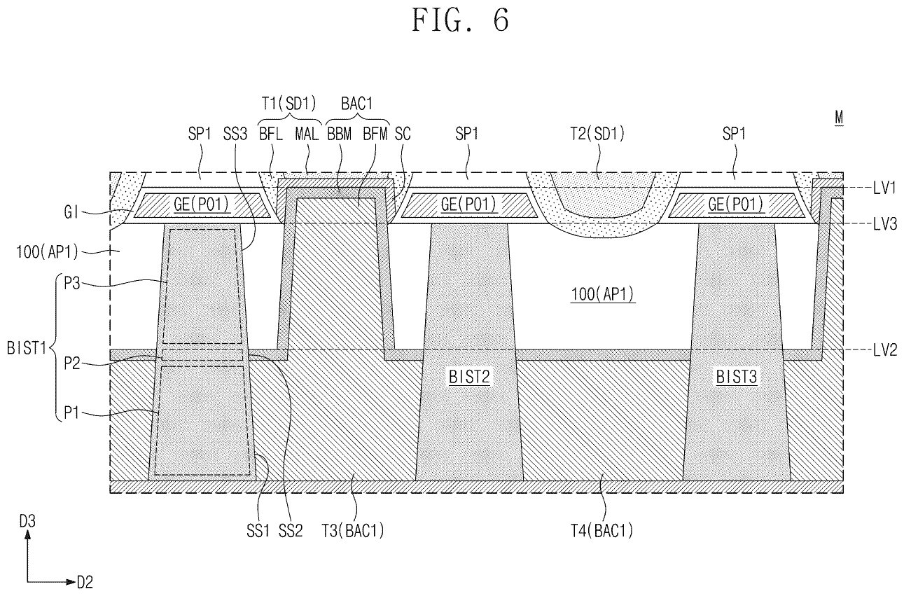

FIG. 6 is an enlarged view illustrating region M of FIG. 5A. Hereinafter, a semiconductor device according to an embodiment of the inventive concept will be described with reference to FIG. 6. For simplification of description, duplicate descriptions may be omitted.

The first semiconductor patterns SP1 of the first channel pattern CH1 may be provided on the substrate 100 horizontally spaced apart from each other. The source/drain patterns SD1 connected to the first semiconductor patterns SP1 may each include a first pattern T1 and a second pattern T2 interposed between the first semiconductor patterns SP1.

The first backside active contact BAC1 may include a third pattern T3 electrically connected to the first pattern T1 and a fourth pattern T4 separated from the second pattern T2. Backside isolation structures may each penetrate the substrate 100 and the first backside active contact BAC1 and may be horizontally spaced apart from each other. The backside isolation structures may each include a first backside isolation structure BIST1, a second backside isolation structure BIST2, and a third backside isolation structure BIST3. The third pattern T3 may be disposed between the first and second backside isolation structures BIST1 and BIST2, and the fourth pattern T4 may be disposed between the second and third backside isolation structures BIST2 and BIST3. The metal-semiconductor compound layer SC may be interposed between the first pattern T1 and the third pattern T3.

The first backside isolation structure BIST1 may include a first part P1, a second part P2 on the first part P1, and a third part P3 on the second part P2. The first to third parts P1, P2, and P3 may respectively include a first side surface SS1, a second side surface SS2, and a third side surface SS3 corresponding thereto. For example, with the second part P2 on the first part P1, and the third part P3 on the second part P2, the second side surface SS2 may extend upward from the first side surface SS1, and the third side surface SS3 may extend upward from the second side surface SS2. The first to third side surfaces SS1, SS2, and SS3 may form a linear side surface of the first backside isolation structure BIST1.

The first part P1 may be disposed with the backside conductive pattern BFM at side portions thereof. The first part P1 may be in direct contact with the backside conductive pattern BFM, and may not be in direct contact with the backside barrier pattern BBM. For example, the first part P1 may be disposed at a level below the backside barrier pattern BBM. The backside barrier pattern BBM may be disposed at side portions of second part P2. The second part P2 may be in direct contact with the backside barrier pattern BBM. The substrate 100 or the first active pattern AP1 may be disposed at side portions of the third part P3. The third part P3 may be in direct contact with the substrate 100 or the first active pattern AP1. That is, the first side surface SS1 may be in direct contact with the backside conductive pattern BFM, and the second side surface SS2 may be in direct contact with the backside barrier pattern BBM. The third side surface SS3 may be in direct contact with the substrate 100, which may be a silicon-based substrate.

An uppermost surface of the third pattern T3 of the first backside active contact BAC1 may be located at a first level LV1. An uppermost surface of the fourth pattern T4 of the first backside active contact BAC1 may be located at a second level LV2. An uppermost surface of each of the first to third backside isolation structures BIST1, BIST2, and BIST3 may be located at a third level LV3. The first to third levels LV1, LV2 and LV3 may be defined as positions in the third direction D3.

The first level LV1 may be the same as or higher than a level of an upper surface of the gate insulating film GI. The second level LV2 may be the same as a level of a lower surface of the substrate 100. The third level LV3 may be higher than the second level LV2, and lower than the first level LV1. That is, an uppermost surface of each of the first to third backside isolation structures BIST1, BIST2, and BIST3 may be located between an upper surface of the third pattern T3 and an upper surface of the fourth pattern T4. The third level LV3 may be the same as a level of the lower surface of the gate insulating film GI.

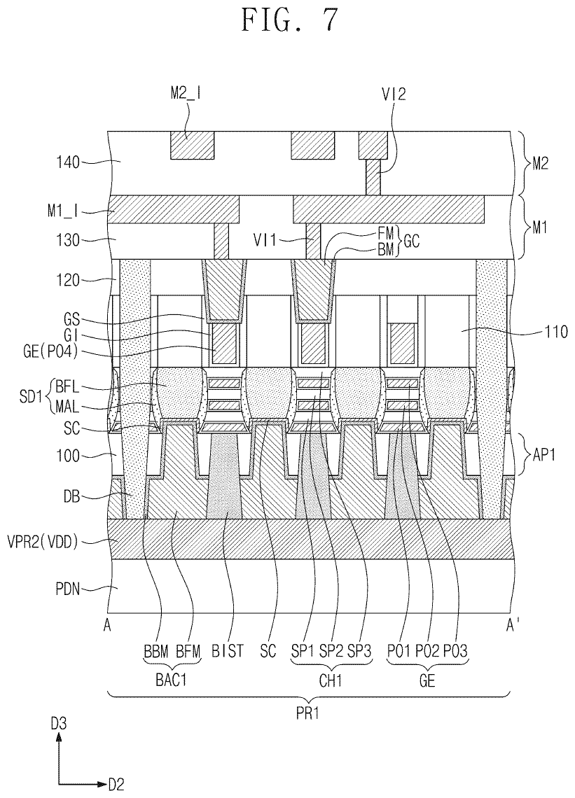

FIG. 7 is a cross-sectional view for describing a semiconductor device according to another embodiment of FIG. 5A. Referring to FIG. 7, the first backside active contact BAC1 penetrating the substrate 100 to vertically extend from the second lower power line VPR2 to the first source/drain pattern SD1 may be provided. Specifically, the first backside active contact BAC1 may be disposed under the substrate 100 to vertically extend from the second lower power line VPR2 to the first source/drain pattern SD1.

The first backside active contact BAC1 may have a form of a conductive column vertically and electrically connecting the second lower power line VPR2 and the first source/drain pattern SD1. The drain voltage VDD may be applied to the first source/drain pattern SD1 through the first backside active contact BAC1.

According to an embodiment, since the first backside active contact BAC1 is electrically entirely connected to the first source/drain pattern SD1 in a unit cell, the upper active contact AC (see FIG. 5A) may not be formed. Accordingly, the upper active contact AC may not be formed on a front surface of the semiconductor device so that a short circuit phenomenon between a gate contact and the upper active contact may be prevented. In addition, contacts may be formed on the front surface of the semiconductor device at a relatively low density to improve efficiency in manufacturing the semiconductor device.

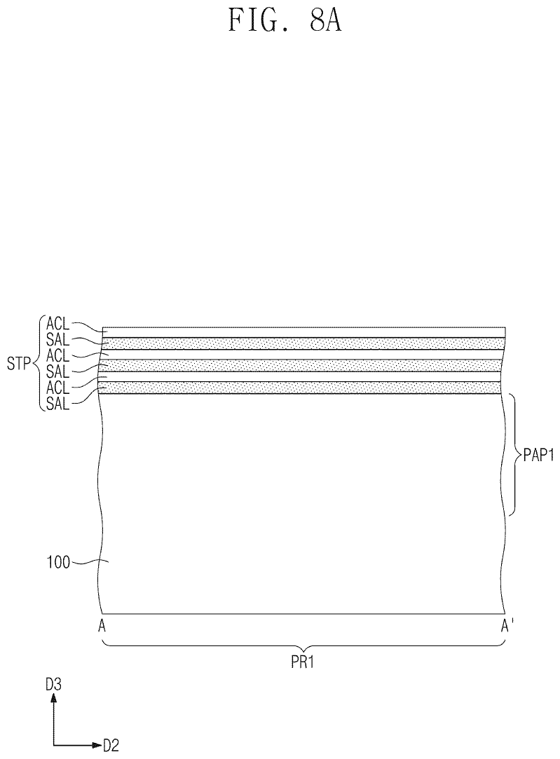

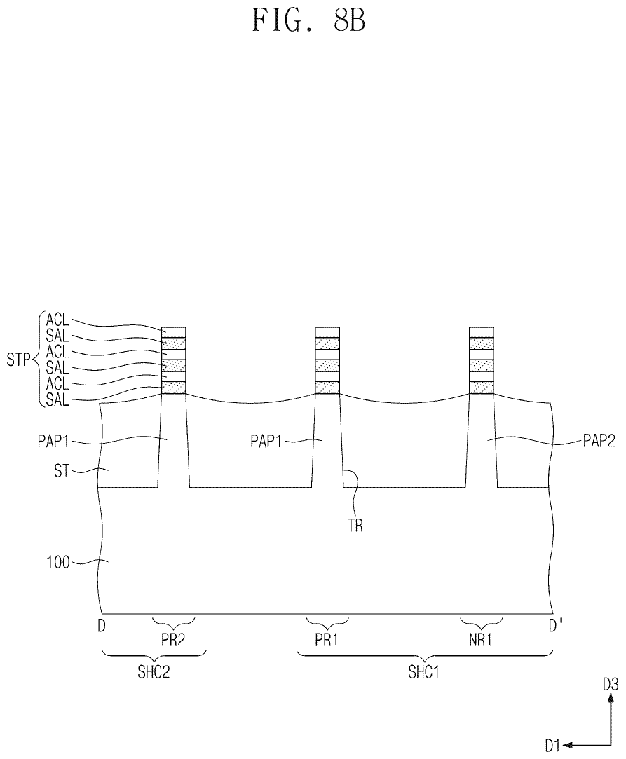

Each of FIGS. 8A and 8B, FIGS. 9A and 9B, FIGS. 10A to 10C, FIGS. 11A to 11C, FIGS. 12A to 12C, FIGS. 13A to 13D, FIGS. 14A to 14D, FIGS. 15A to 15D, FIGS. 16A to 16D, and FIGS. 17A to 17D are cross-sectional views for describing a method for manufacturing a semiconductor device according to embodiments of the inventive concept. Specifically, FIGS. 8A, 9A, 10A, 11A, 12A, 13A, 14A, 15A, 16A, and 17A are cross-sectional views corresponding to line A-A′ of FIG. 4A. FIGS. 10B, 11B, 12B, 13B, 14B, 15B, 16B, and 17B are cross-sectional views corresponding to line B-B′ of FIG. 4A. FIGS. 10C, 11C, 13C, 14C, 15C, 16C, and 17C are cross-sectional views corresponding to line C-C′ of FIG. 4A. FIGS. 8B, 9B, 12C, 13D, 14D, 15D, 16D, and 17D are cross-sectional views corresponding to line D-D′ of FIG. 4A.

Referring to FIGS. 8A and 8B, a substrate 100 including the first and second PMOSFET regions PR1 and PR2 and the first and second NMOSFET regions NR1 and NR2 may be provided. For example, the substrate 100 may be a silicon wafer.

First semiconductor layers ACL and second semiconductor layers SAL alternately stacked may be formed on the substrate 100. The first semiconductor layers ACL may include at least one of silicon (Si), germanium (Ge), and silicon-germanium (SiGe), and the second semiconductor layers SAL may include another one among silicon (Si), germanium (Ge), or silicon-germanium (SiGe).

While three first semiconductor layers ACL and three second semiconductor layers SAL are illustrated in FIG. 8, the number of layers may be varied. For example, the number of layers may be varied to control a number of layers in a channel pattern and/or a gate electrode formed later.

The second semiconductor layer SAL may have etching selectivity with respect to the first semiconductor layer ACL. For example, the first semiconductor layers ACL may include silicon (Si), and the second semiconductor layers SAL may include silicon-germanium (SiGe). The second semiconductor layers SAL may each have germanium (Ge) at a concentration of about 10 at % to about 30 at %.

Mask patterns may be respectively formed on the first and second PMOSFET regions PR1 and PR2 and the first and second NMOSFET regions NR1 and NR2 of the substrate 100. The mask pattern may have a form of a line or bar extending in the second direction D2.

A trench TR defining a first active pattern PAP1 and a second active pattern PAP2 may be formed by performing a patterning process using the mask patterns as etching masks. The first active pattern PAP1 may be formed on each of the first and second PMOSFET regions PR1 and PR2. The second active pattern PAP2 may be formed on each of the first and second NMOSFET regions NR1 and NR2. In a plan view, the first and second active patterns PAP1 and PAP2 may have a form of a line extending parallel to each other in the second direction D2.

A stack pattern STP may be formed on each of the first and second active patterns PAP1 and PAP2. The stack pattern STP may include an etch stopping layer ESL. The stack pattern STP may further include the first semiconductor layers ACL and the second semiconductor layers SAL alternately stacked on the etch stopping layer ESL. The stack pattern STP may be formed together with the first and second active patterns PAP1 and PAP2 during the patterning process.

A device isolation film ST that fills the trench TR may be formed. Specifically, an insulating film covering the first and second active patterns PAP1 and PAP2 and the stack patterns STP may be formed on the front surface of the substrate 100. The device isolation film ST may be formed by recessing the insulating film. For example, the device isolation film ST may be formed by recessing the insulating film until the stack patterns STP are exposed.

The device isolation film ST may include an insulating material such as a silicon oxide film. The stack patterns STP may be exposed onto the device isolation film ST. In other words, the stack patterns STP may vertically protrude onto the device isolation film ST.

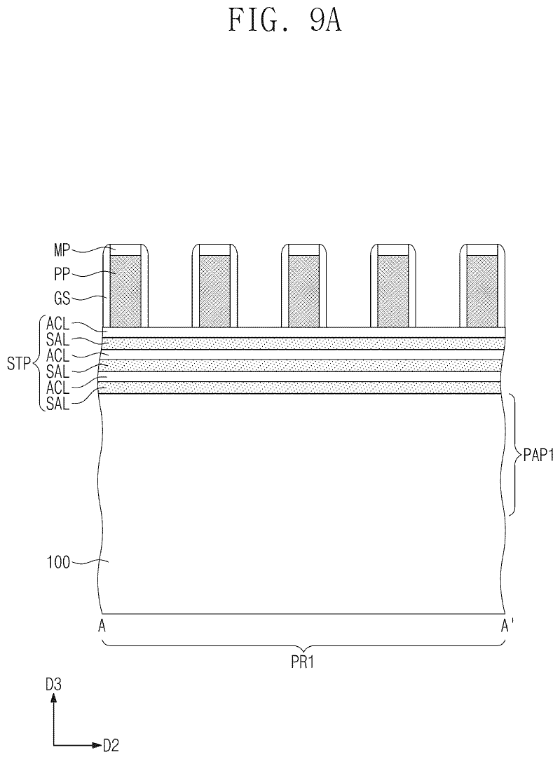

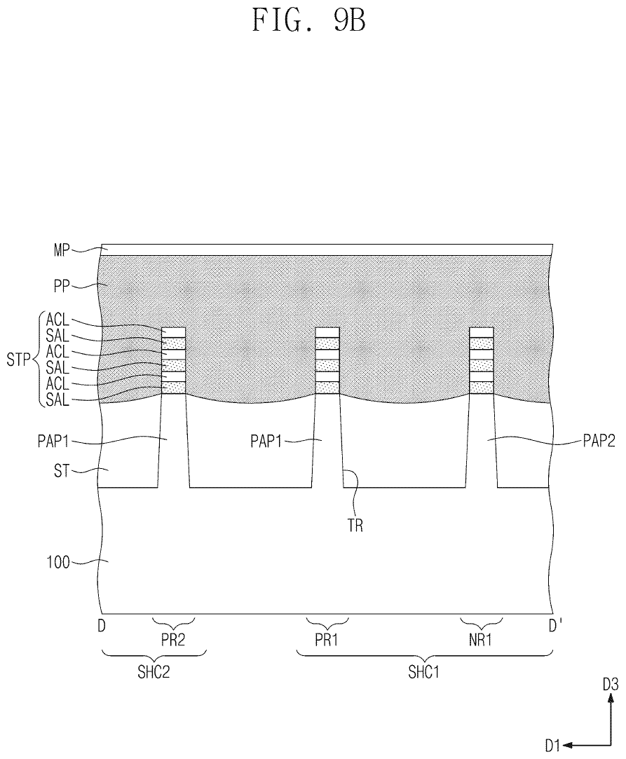

Referring to FIGS. 9A and 9B, sacrificial patterns PP crossing the stack patterns STP may be formed on the substrate 100. The sacrificial patterns PP may be each formed in a form of a line or bar extending in the first direction D1. The sacrificial patterns PP may be arranged with a first pitch along the second direction D2.

Specifically, forming the sacrificial patterns PP may include forming a sacrificial film on the front surface of the substrate 100, forming hard mask patterns MP on the sacrificial film, and patterning the sacrificial film using the hard mask patterns MP as etching masks. The sacrificial film may include polysilicon.

A pair of gate spacers GS may be formed on both sidewalls of each of the sacrificial patterns PP. Forming the gate spacers GS may include conformally forming a gate spacer film on the front surface of the substrate 100, and anisotropically etching the gate spacer film. The gate spacer film may include at least one of SiCN, SiCON, or SiN. As another example, the gate spacer film may be a multi-layered film including at least two of SiCN, SiCON, or SiN.

Referring to FIGS. 10A to 10C, first recesses RS1 may be formed in the stack pattern STP on the first active pattern PAP1. Second recesses RS2 may be formed in the stack pattern STP on the second active pattern PAP2. While the first and second recesses RS1 and RS2 are formed, the device isolation film ST on both sides of each of the first and second active patterns PAP1 and PAP2 may be further recessed. (see FIG. 10C).

Specifically, the first recesses RS1 may be formed by etching the stack pattern STP on the first active pattern PAP1 using the hard mask patterns MP and the gate spacers GS as etching masks. The first recess RS1 may be formed between a pair of sacrificial patterns PP. The second recesses RS2 in the stack pattern STP on the second active pattern PAP2 may be formed in the same process as a process of forming the first recesses RS1.

Referring to FIG. 10C, a fence pattern FNP may be formed on each of the first and second active patterns PAP1 and PAP2. The fence pattern FNP may be a part of the remaining gate spacer GS.

Referring to FIGS. 10A to 10C, the first to third semiconductor patterns SP1, SP2, and SP3 sequentially stacked between the first recesses RS1 adjacent to each other may be respectively formed from the first semiconductor layers ACL. The first to third semiconductor patterns SP1, SP2, and SP3 sequentially stacked between the second recesses RS2 adjacent to each other may be respectively formed from the first semiconductor layers ACL. The first to third semiconductor patterns SP1, SP2, and SP3 between the first recesses RS1 adjacent to each other may constitute the first channel pattern CH1. The first to third semiconductor patterns SP1, SP2, and SP3 between the second recesses RS2 adjacent to each other may constitute the second channel pattern CH2.

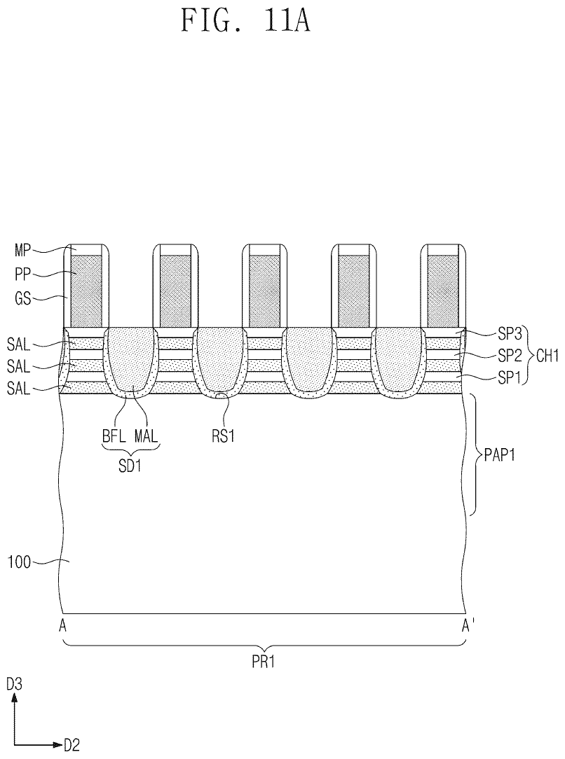

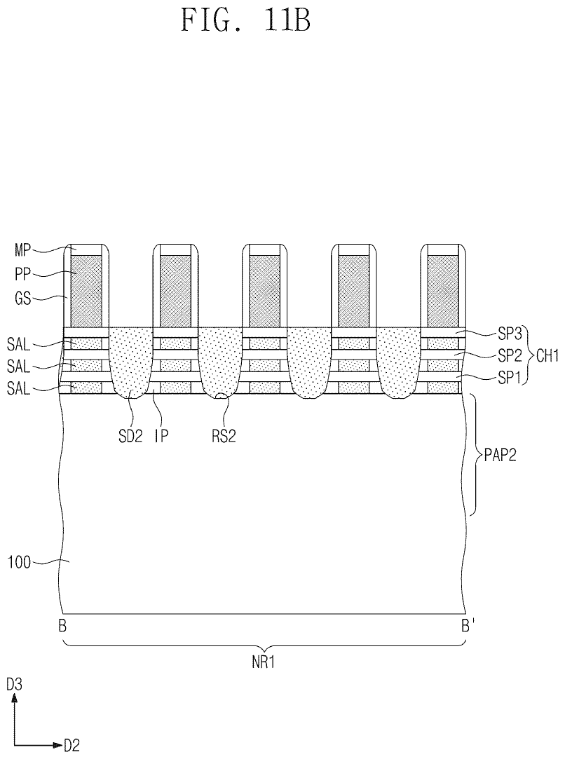

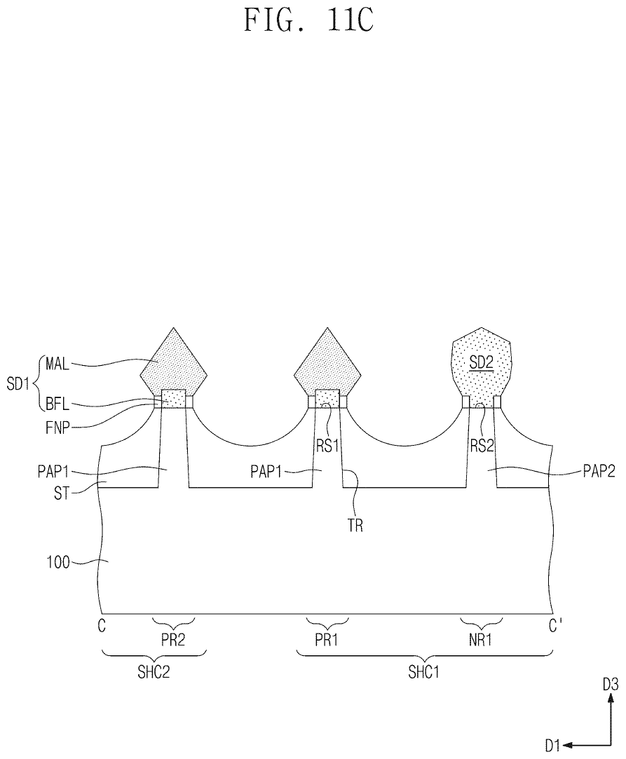

Referring to FIGS. 11A to 11C, the first source/drain patterns SD1 may be respectively formed in the first recesses RS1. Specifically, the buffer layer BFL may be formed by performing a first SEG process in which an inner sidewall of the first recess RS1 may be used as a seed layer. The buffer layer BFL may be grown using the substrate 100 and the first to third semiconductor patterns SP1, SP2, and SP3 exposed by the first recess RS1 as seeds. For example, the first SEG process may include a chemical vapor deposition (CVD) process or a molecular beam epitaxy (MBE) process.

The buffer layer BFL may include a semiconductor element (for example, SiGe) having a greater lattice parameter than a semiconductor element of the substrate 100. The buffer layer BFL may contain germanium (Ge) at a relatively low concentration. According to another embodiment of the inventive concept, the buffer layer BFL may contain silicon (Si) and may not include germanium (Ge). The buffer layer BFL may have germanium (Ge) at a concentration of 0 at % to about 30 at %.

The main layer MAL may be formed by performing a second SEG process on the buffer layer BFL. The main layer MAL may be formed so as to completely or almost fill the first recess RS1. The main layer MAL may contain germanium (Ge) at a relatively high concentration. For example, the main layer MAL may have germanium (Ge) at a concentration of about 30 at % to about 70 at %.

According to an embodiment of the inventive concept, a capping layer may be formed by performing a third SEG process on the main layer MAL. The capping layer may include silicon (Si). The capping layer may have silicon (Si) at a concentration of about 98 at % to 100 at %.

While the buffer layer BFL and the main layer MAL are formed, impurities (for example, boron, gallium, or indium), which may cause the first source/drain pattern SD1 to be the P-type, may be in-situ injected. As another example, after the first source/drain pattern SD1 is formed, the impurities may be injected into the first source/drain pattern SD1.

The second source/drain patterns SD2 may be respectively formed in the second recesses RS2. Specifically, the second source/drain pattern SD2 may be formed by performing a selective epitaxial growth (SEG) process in which an inner sidewall of the second recess RS2 may be used as a seed layer. For example, the second source/drain pattern SD2 may include the same semiconductor element (for example, Si) as the substrate 100.

While the second source/drain pattern SD2 is formed, impurities (for example, phosphorus, arsenic, or antimony), which may cause the second source/drain pattern SD2 to be an N-type, may be in-situ injected. As another example, after the second source/drain pattern SD2 is formed, the impurities may be injected into the second source/drain pattern SD2.

According to an embodiment of the inventive concept, before the second source/drain pattern SD2 is formed, the second semiconductor layer SAL exposed through the second recess RS2 may be partially substituted with an insulating material to form an inner spacer IP. For example, the inner spacers IP may be respectively formed between the second source/drain pattern SD2 and the second semiconductor layers SAL.

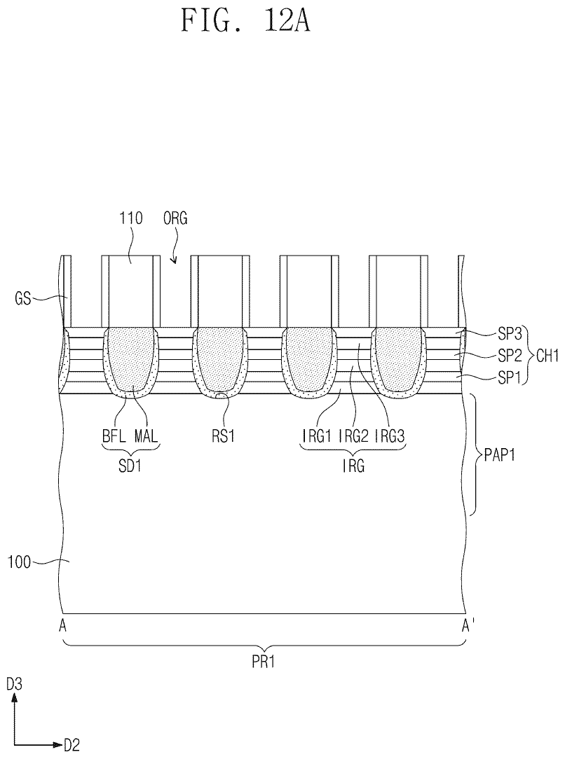

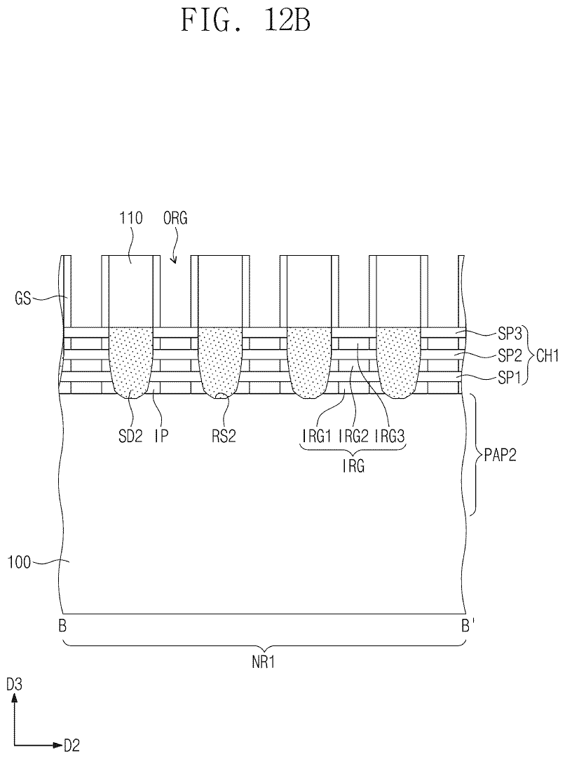

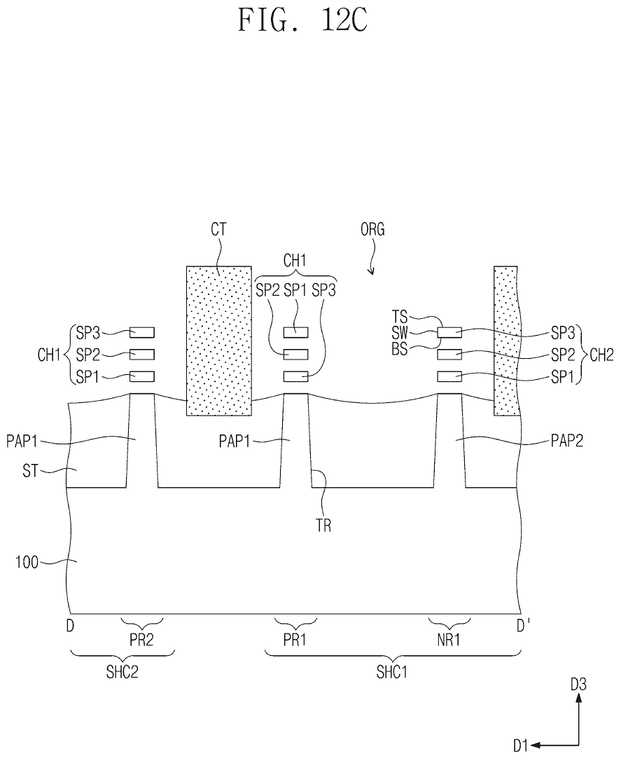

Referring to FIGS. 12A to 12C, the first interlayer insulating film 110 may be formed. The first interlayer insulating film 110 may cover the first and second source/drain patterns SD1 and SD2, the hard mask patterns MP, and the gate spacers GS. For example, the first interlayer insulating film 110 may include a silicon oxide film.

The first interlayer insulating film 110 may be planarized. For example, the first interlayer insulating film 110 may be planarized until upper surfaces of the sacrificial patterns PP are exposed. The first interlayer insulating film 110 may be planarized by using an etch-back process or a chemical mechanical polishing (CMP) process. At least a portion of the hard mask patterns MP may be removed during the planarization process. For example, the hard mask patterns MP may be fully removed during the planarization process. Following the planarization process, an upper surface of the first interlayer insulating film 110 may be coplanar with the upper surfaces of the sacrificial patterns PP and upper surfaces of the gate spacers GS.

A region of the sacrificial pattern PP may be selectively opened by using a photolithography process. For example, a region, of the sacrificial patterns PP, on the third and fourth boundaries BD3 and BD4 of the first single height cell SHC1 may be selectively opened. The opened region of the sacrificial patterns PP may be selectively removed by etching. The gate cutting pattern CT may be formed in the region in which the sacrificial patterns PP is removed (see FIG. 12C). For example, the gate cutting pattern CT may be formed by filling the region in which the sacrificial patterns PP is removed with an insulating material.

The exposed sacrificial patterns PP may be selectively removed. An outer region ORG exposing the first and second channel patterns CH1 and CH2 may be formed by removing the sacrificial patterns PP (see FIG. 12C). Removing the sacrificial patterns PP may include a wet etching process using an etchant selectively etching polysilicon.

Inner regions IRG may be formed by selectively removing the second semiconductor layers SAL exposed through the outer region ORG (see FIGS. 12A and 12B). Specifically, the second semiconductor layers SAL may be removed in a state in which the first to third semiconductor patterns SP1, SP2, and SP3 may remain by performing an etching process of selectively etching the second semiconductor layers SAL. The etching process may have a high etch-rate with respect to silicon-germanium having a relatively high germanium concentration. For example, the etching process may have a high etch-rate with respect to silicon-germanium having a germanium concentration higher than about 10 at %.

During the etching process, the second semiconductor layers SAL on the first and second PMOSFET regions PR1 and PR2 and the first and second NMOSFET regions NR1 and NR2 may be removed. For example, the second semiconductor layers SAL on the first and second PMOSFET regions PR1 and PR2 and the first and second NMOSFET regions NR1 and NR2 may be completely removed. The etching process may be wet etching. An etching material used in the etching process may remove the second semiconductor layer SAL having a relatively high germanium concentration. Meanwhile, the first source/drain pattern SD1 on the first and second PMOSFET regions PR1 and PR2 may be protected during the etching process by the buffer layer BFL having a relatively low germanium concentration.

Referring to FIG. 12C, the stacked first to third semiconductor patterns SP1, SP2, and SP3 may remain on each of the first and second active patterns PAP1 and PAP2 by selectively removing the second semiconductor layers SAL. First to third inner regions IRG1, IRG2, and IRG3 may be respectively formed through regions in which the second semiconductor layers SAL are removed. Specifically, a first inner region IRG1 may be formed between the active patterns PAP1 or PAP2 and the first semiconductor pattern SP1, a second inner region IRG2 may be formed between the first semiconductor pattern SP1 and the second semiconductor pattern SP2, and a third inner region IRG3 may be formed between the second semiconductor pattern SP2 and the third semiconductor pattern SP3.

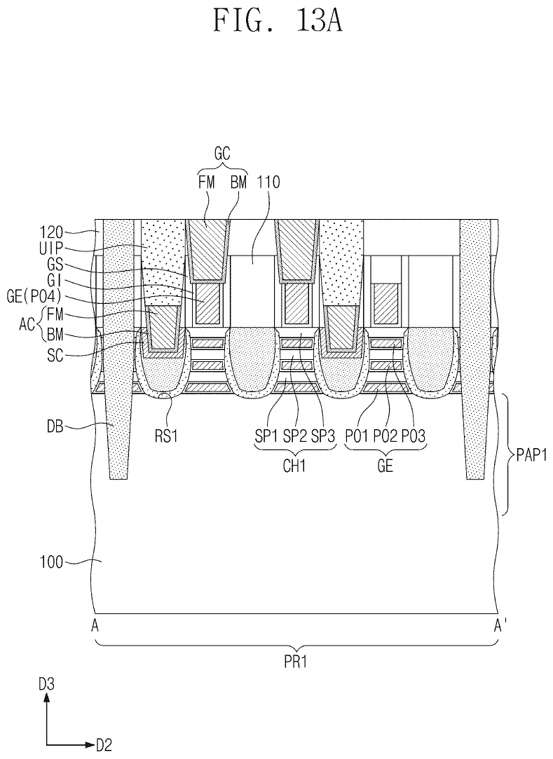

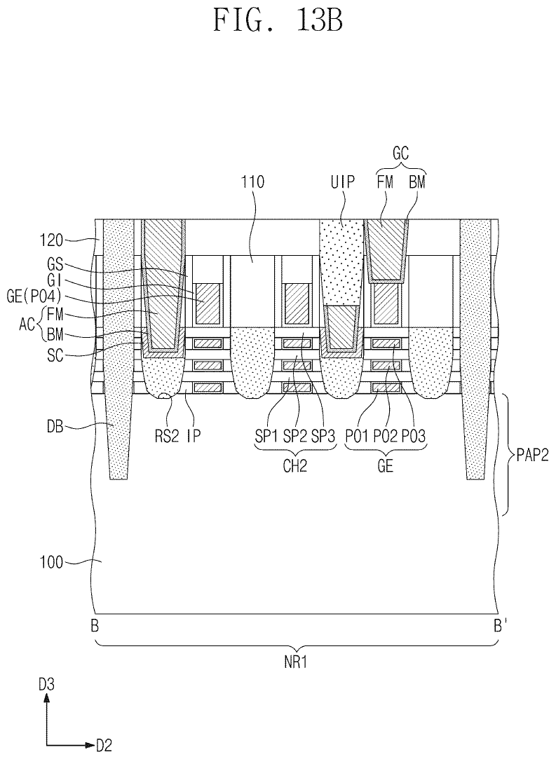

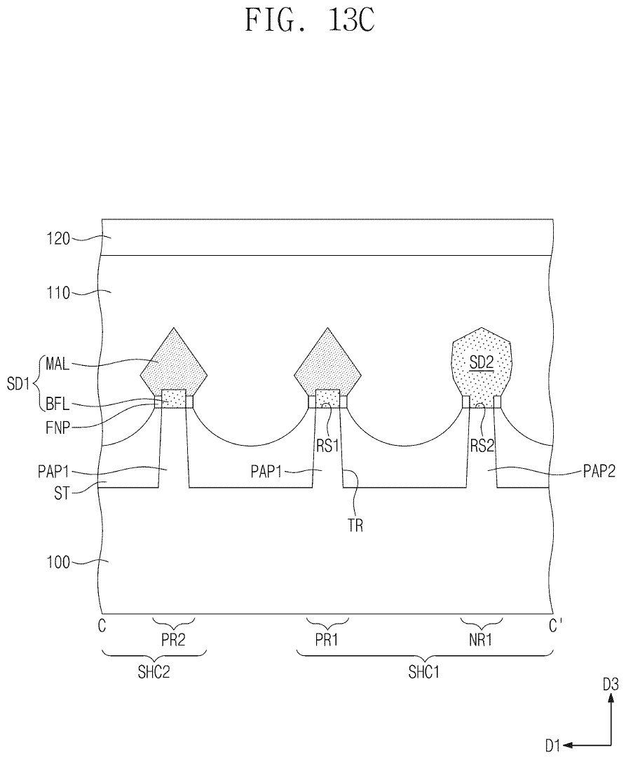

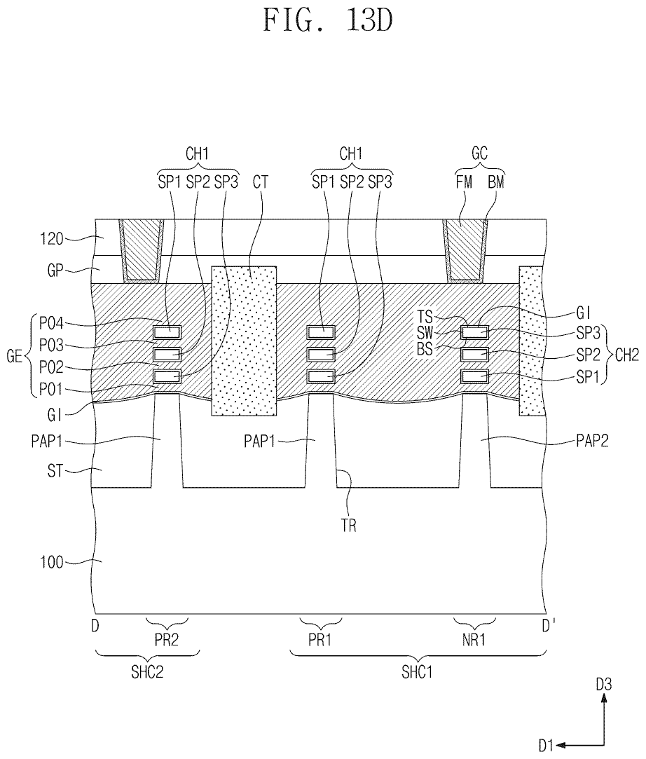

Referring to FIGS. 13A to 13D, the gate insulating film GI may be conformally formed on the exposed first to third semiconductor patterns SP1, SP2, and SP3. The gate electrode GE may be formed on the gate insulating film GI. The gate electrode GE may include the first to third inner electrodes PO1, PO2, and PO3 respectively formed in the first to third inner regions IRG1, IRG2, and IRG3, and the outer electrode PO4 formed in the outer region ORG.

The gate electrode GE may be recessed, and the height thereof may be reduced. While the gate electrode GE may be recessed, upper parts of the gate cutting patterns CT may be also recessed. For example, an upper part of the gate cutting patterns CT may extend above the gate electrode GE. The gate capping pattern GP may be formed on the recessed gate electrode GE. The gate capping pattern GP may cover the gate electrode GE and the gate cutting patterns CT. For example, the gate capping pattern GP may be formed on an upper surface of the gate cutting patterns CT and exposed side surfaces of the gate cutting patterns CT.

The second interlayer insulating film 120 may be formed on the first interlayer insulating film 110. The second interlayer insulating film 120 may include a silicon oxide film. The upper active contact AC may be formed to penetrate a portion of the second interlayer insulating film 120 and a portion of the first interlayer insulating film 110. The upper active contact AC penetrating the second interlayer insulating film 120 and the first interlayer insulating film 110 may be electrically connected to at least one of the first and second source/drain patterns SD1 and SD2. The gate contact GC may be formed to penetrate at least a portion of the second interlayer insulating film 120 and the gate capping pattern GP. The gate contact GC penetrating the second interlayer insulating film 120 and the gate capping pattern GP may be electrically connected to the gate electrode GE.

Forming each of the upper active contact AC and the gate contact GC may include forming the barrier pattern BM and forming the conductive pattern FM on the barrier pattern BM. The barrier pattern BM may be conformally formed, and may include a metal film/metal nitride film. The conductive pattern FM may include metal having low resistance.

Referring to FIG. 4A, and FIGS. 5A to 5D, the third interlayer insulating film 130 may be formed on the upper active contacts AC and the gate contacts GC. The first metal layer M1 may be formed in the third interlayer insulating film 130. The first metal layer M1 may include a first line M1_I electrically connected to at least one of the upper active contacts AC or the gate contacts GC. The fourth interlayer insulating film 140 may be formed on the third interlayer insulating film 130. The second metal layer M2 may be formed in the fourth interlayer insulating film 140.

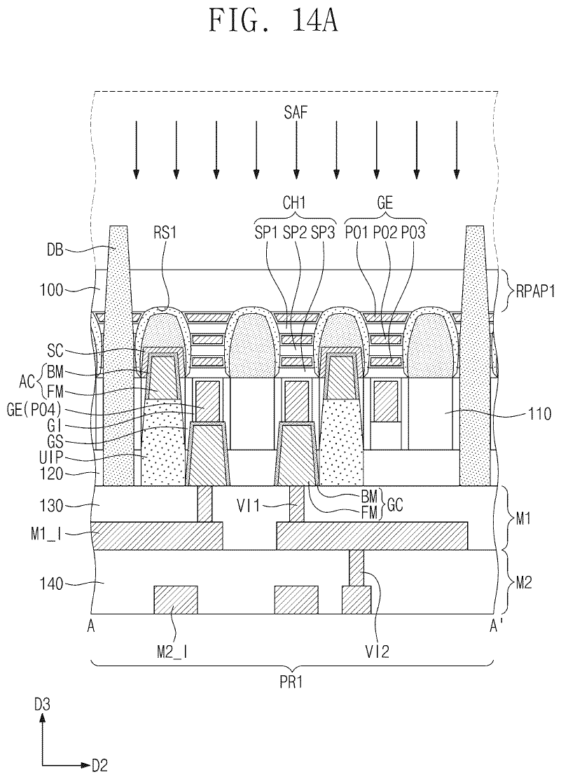

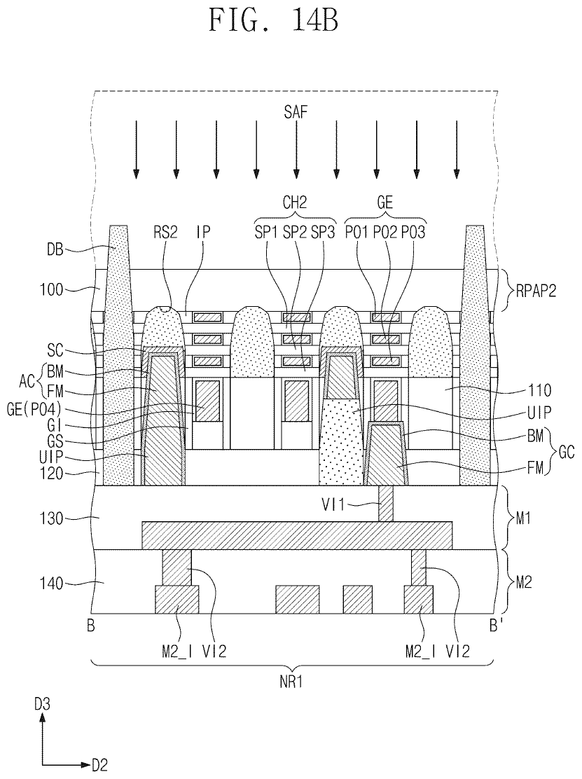

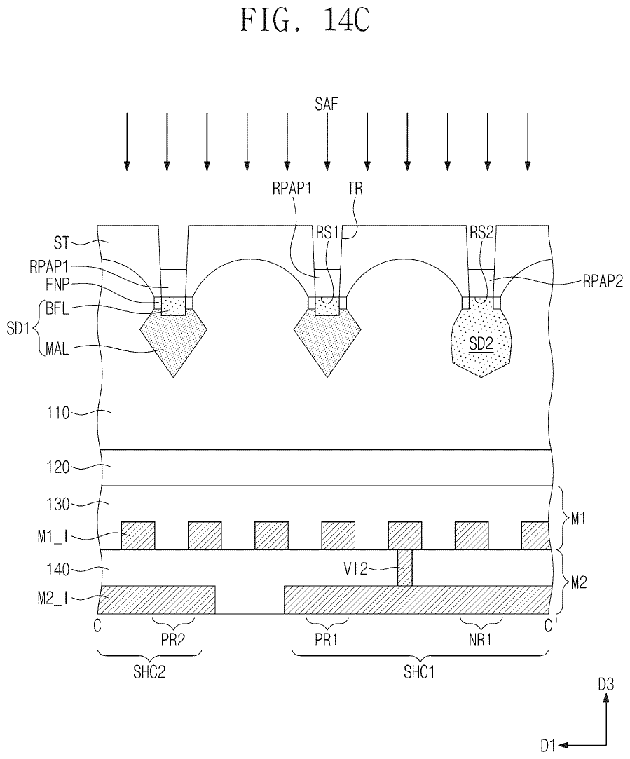

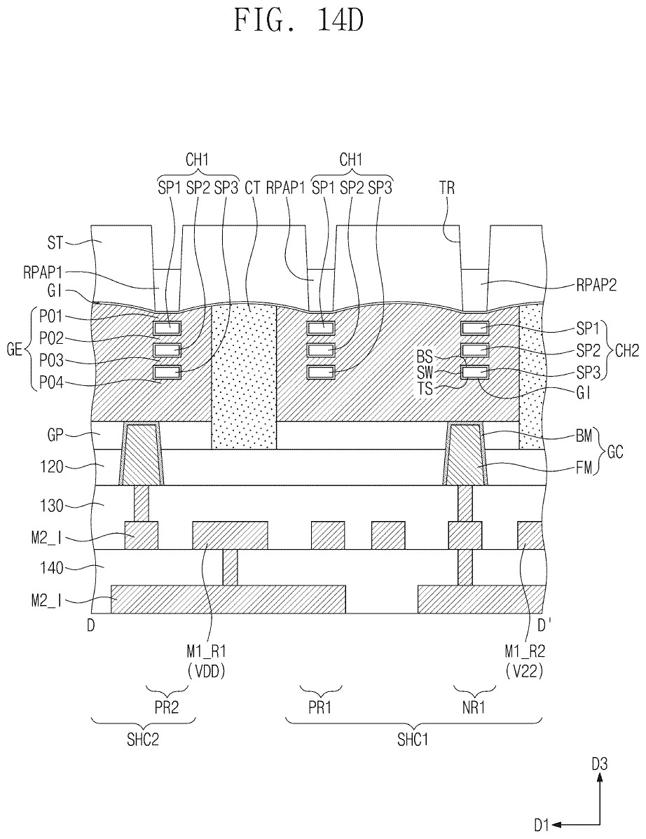

After a BEOL process is completed, the substrate 100 described with reference to FIGS. 8A and 8B, FIGS. 9A and 9B, FIGS. 10A to 10C, FIGS. 11A to 11C, FIGS. 12A to 12C, FIGS. 13A to 13D may be turned upside down. Since the substrate 100 is turned upside down, hereinafter, in describing with reference to FIGS. 14A to 14D, FIGS. 15A to 15D, FIGS. 16A to 16D, and FIGS. 17A to 17D, ‘an upper surface’ and ‘an upper part’ may respectively mean ‘a lower surface’ and ‘a lower part’ from a point of view of a completely manufactured three-dimensional semiconductor device described with reference to FIGS. 5A to 5D, and ‘a lower surface’ and ‘a lower part’ may respectively mean ‘an upper surface’ and ‘an upper part’ from the point of view of the completely manufactured three-dimensional semiconductor device described with reference to FIGS. 5A to 5D.

Referring to FIGS. 14A to 14D, after the BEOL process is completed, a bottom surface of the substrate 100 may be exposed by turning the substrate 100 upside down. The exposed substrate 100 may be partially removed.

According to an embodiment of the inventive concept, partially removing the substrate 100 may include reducing a thickness of the substrate 100 by performing a planarization process (SAF) on the bottom surface of the substrate 100 and performing a cleaning process of selectively removing silicon (Si) on the substrate 100. The cleaning process may be performed until an upper surface and a side surface of the isolation structure DB are partially exposed.

A first remaining active pattern RPAP1 may be formed in a region in which the first active pattern PAP1 is present by partially removing the substrate 100. A second remaining active pattern RPAP2 may be formed in a region in which the second active pattern PAP2 is present by partially removing the substrate 100 (see FIGS. 14A and 14B).

First and second remaining active patterns RPAP1 and RPAP2 may be formed on the first and second source/drain patterns SD1 and SD2 by partially removing the substrate 100. The device isolation film ST may not be removed by performing the cleaning process of selectively removing silicon (see FIG. 14C).

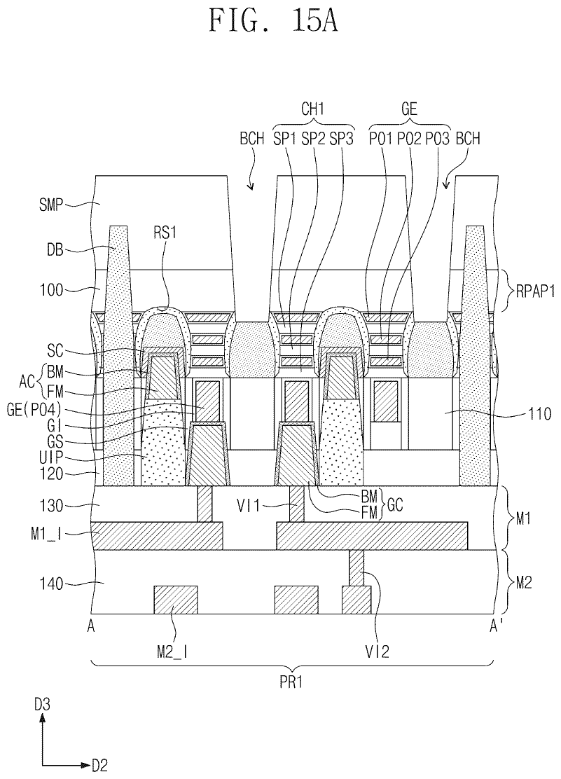

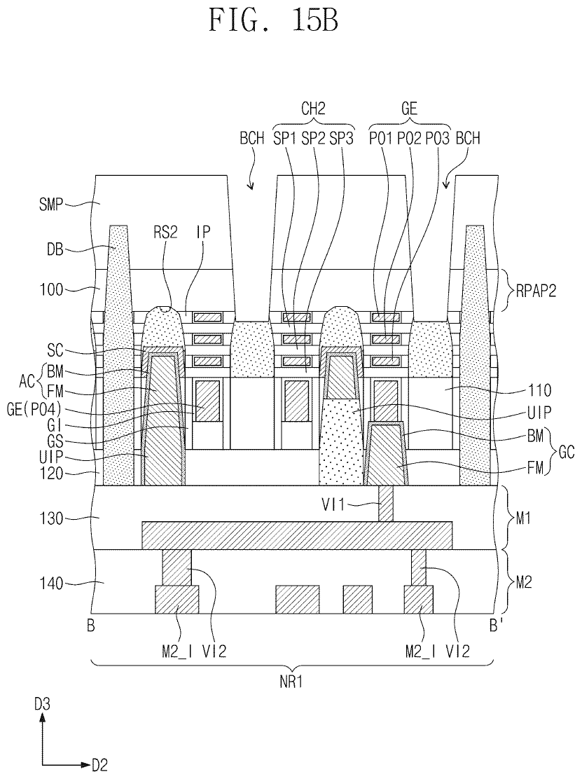

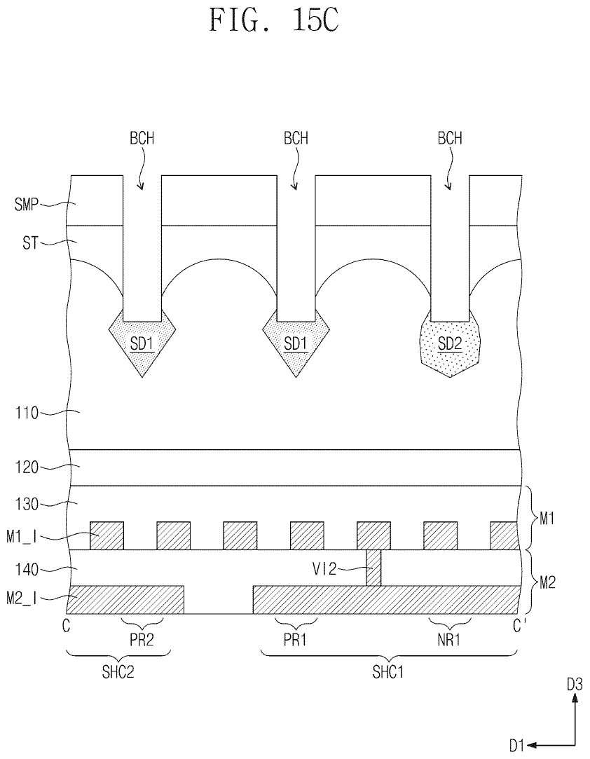

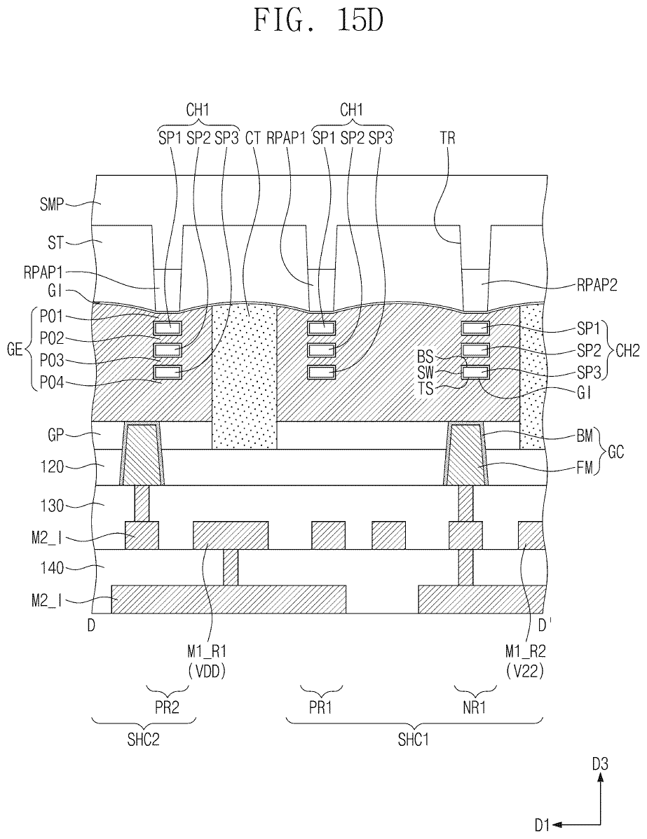

Referring to FIGS. 15A to 15D, a SOH mask pattern SMP may be formed in a region in which the substrate 100 is partially removed. The SOH mask pattern SMP may cover the isolation structure DB, the first and second remaining active patterns RPAP1 and RPAP2, and the device isolation film ST. The SOH mask pattern SMP may be formed through a photolithography process. Backside contact holes BCH may be formed by performing an anisotropic etching process on the substrate 100 using the SOH mask pattern SMP as an etching mask. The backside contact holes BCH may expose the first source/drain pattern SD1 and the second source/drain pattern SD2. Specifically, the backside contact holes BCH may expose the source/drain pattern SD1 or SD2 not being connected to the upper active contact AC. The backside contact holes BCH may have a tapered shape. For example, the backside contact holes BCH may have a relatively narrow width at the source/drain pattern SD1 or SD2 and a relatively wide width away from the source/drain pattern SD1 or SD2.

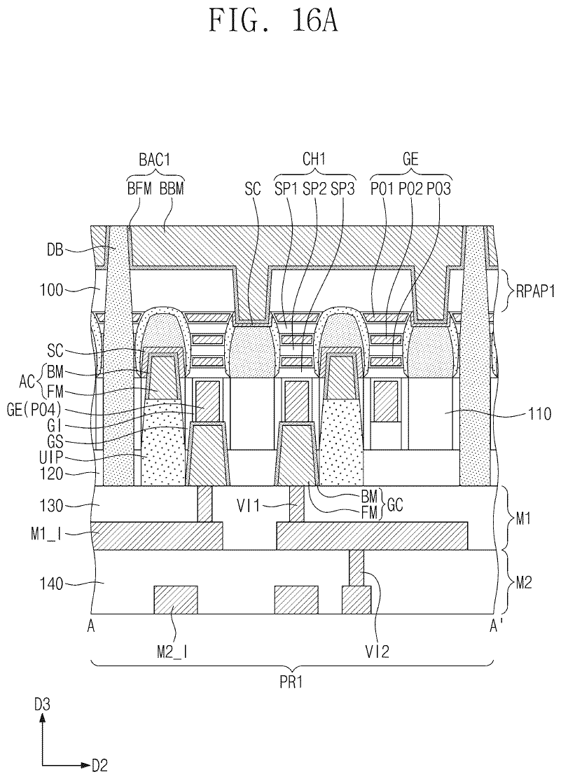

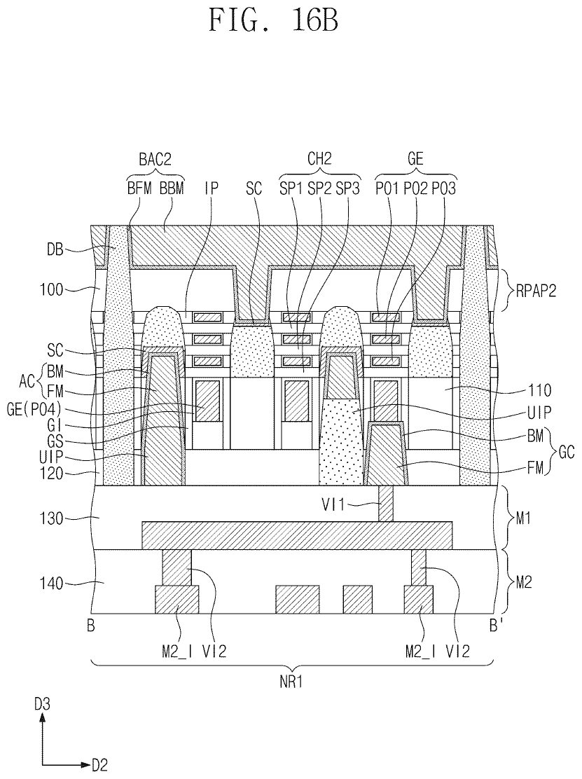

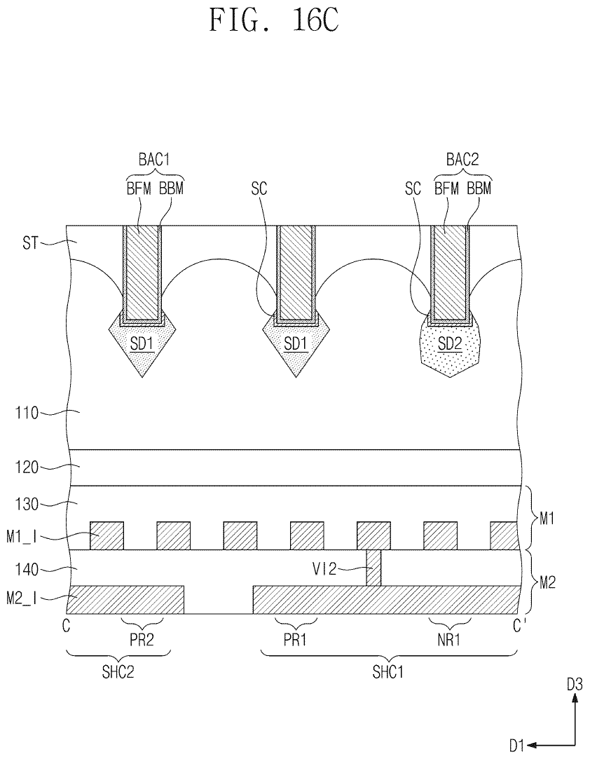

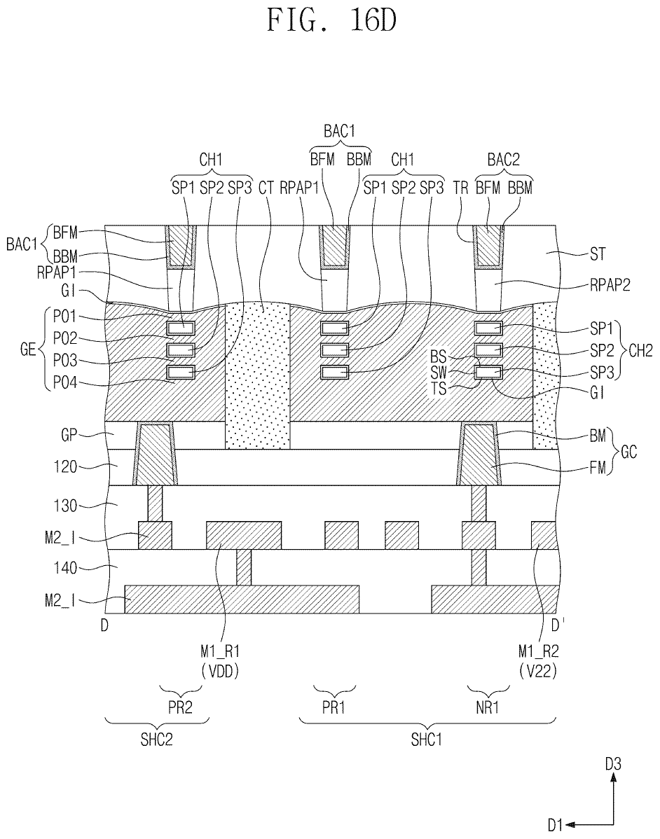

Referring to FIGS. 16A to 16D, the SOH mask pattern SMP may be selectively removed. After the SOH mask pattern SMP is removed, the backside barrier pattern BBM and the backside conductive pattern BFM may be formed on the backside contact holes BCH, the substrate 100, and the isolation structure DB. The metal-semiconductor compound layer SC may be formed between the source/drain pattern SD1 or SD2 and the backside barrier pattern BBM. The backside active contact BAC1 or BAC2 may be formed by performing a planarization process on the backside conductive pattern BFM until an upper surface of the isolation structure DB is exposed. The planarization process may be a chemical mechanical polishing (CMP) process. In other words, the backside barrier pattern BBM and the backside conductive pattern BFM may constitute the backside active contact BAC1 or BAC2. The backside active contact BAC1 or BAC2 may have a tapered shape. For example, the backside active contact BAC1 or BAC2 may have a relatively narrow width at the source/drain pattern SD1 or SD2 and a relatively wide width away from the source/drain pattern SD1 or SD2.

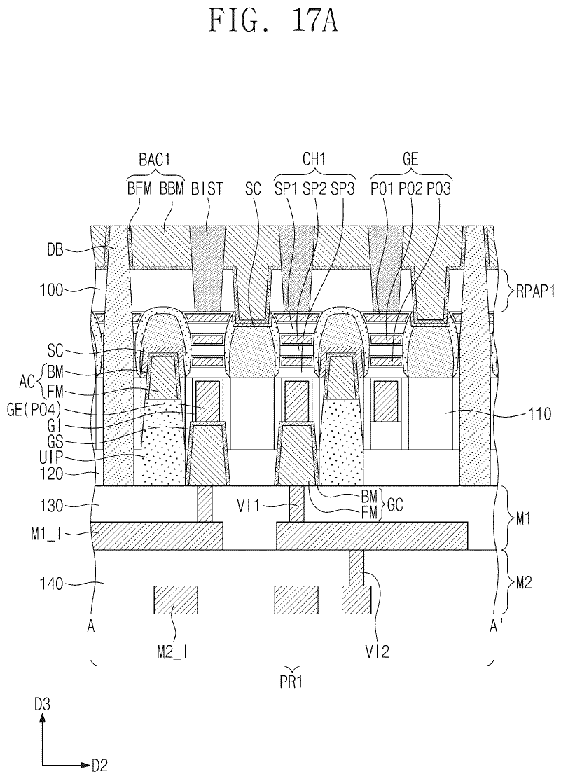

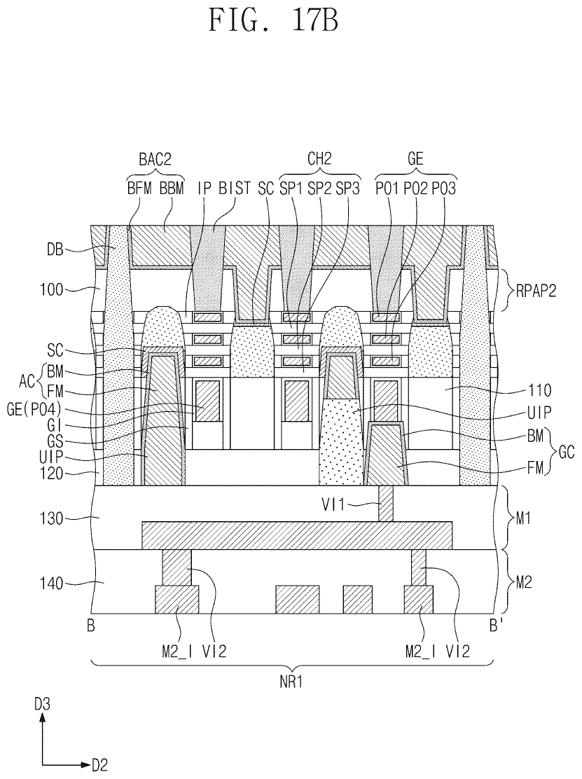

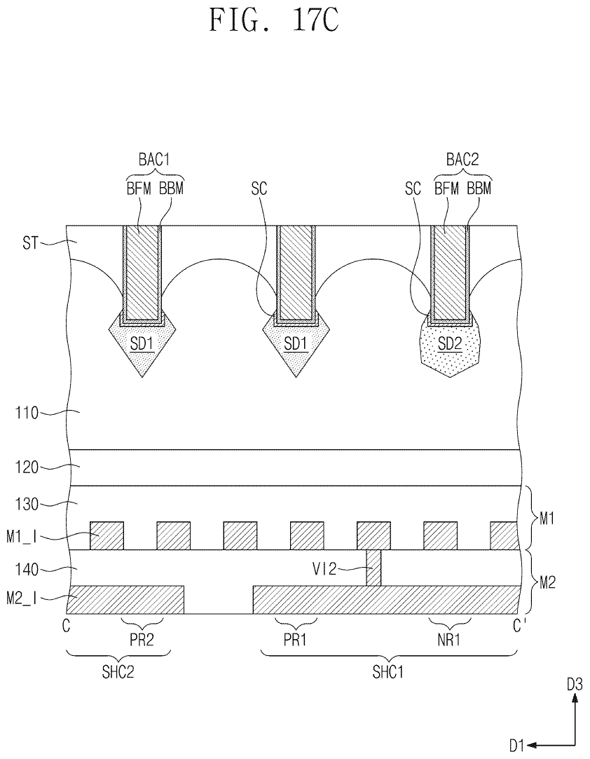

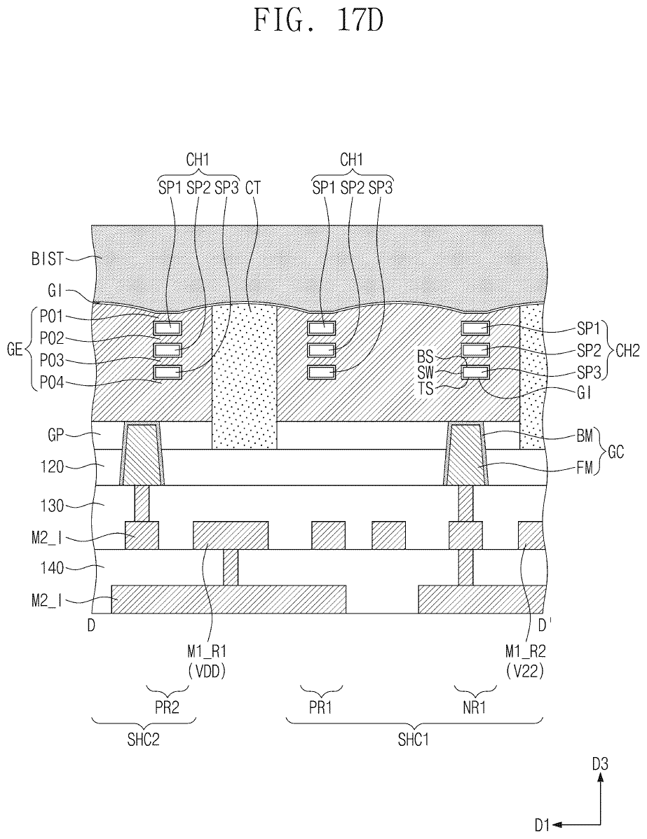

Referring to FIGS. 17A to 17D, an anisotropic etching process may be performed on a region on the gate electrode GE by forming a mask pattern on the backside active contact BAC1 or BAC2 and using the mask pattern as an etching mask. Backside isolation structure holes penetrating the backside active contact BAC1 or BAC2 and the substrate 100 may be formed by performing the anisotropic etching process.

A silicon-based insulating material may be formed in the backside isolation structure holes. The insulating material may be formed by performing a deposition process. The insulating material in the backside isolation structure holes may constitute the backside isolation structure BIST. The backside isolation structure BIST may separate portions of the backside active contact BAC1 from each other. Similarly, the backside isolation structure BIST may separate portions of the backside active contact BAC2 from each other. Since according to a manufacturing method described herein, the backside isolation structure BIST may be formed after the backside active contact BAC1 or BAC2 is formed, and a ratio of the backside barrier pattern BBM in the backside active contact BAC1 or BAC2 may be reduced. That is, the ratio of the backside barrier pattern BBM having a relatively high resistance may be reduced, which may reduce resistance of the backside active contact BAC1 or BAC2, and electrical characteristics of the semiconductor device may be improved.

In addition, the backside active contact BAC1 or BAC2 may be formed having a tapered shape such that an upper part thereof away from the source/drain pattern SD1 or SD2 may have a relatively wide width, and the backside active contact BAC1 or BAC2 may be relatively easily formed. That is, the backside active contact BAC1 or BAC2 having a relatively wide width at an opening thereof may be formed before the backside isolation structure BIST to secure a process margin, and the backside active contact BAC1 or BAC2 may be more easily manufactured given the process margin. Accordingly, a cost associated with a manufacturing process of the semiconductor device may be reduced.

The lower power lines VPR1, VPR2, and VPR3 may be formed on the backside active contact BAC1 or BAC2 and the backside isolation structure BIST. The lower power lines VPR1, VPR2, and VPR3 may be connected to at least one of the backside active contact BAC1 or BAC2. The power transmission network layer PDN may be formed on the lower power lines VPR1, VPR2, and VPR3. The power transmission network layer PDN may be formed so as to apply the source voltage or drain voltage to the lower power lines VPR1, VPR2, and VPR3.

Since in a three-dimensional field effect transistor according to an embodiment of the inventive concept, a backside isolation structure that separates the backside active contact may be formed after a backside active contact is formed, resistance of the backside active contact may be reduced. That is, since the backside isolation structure is formed later, a ratio of a backside barrier pattern having a relatively high resistance in the backside active contact may be reduced to reduce resistance of the backside active contact. Accordingly, electrical characteristics of a semiconductor device may be improved.

Since in the three-dimensional field effect transistor according to an embodiment of the inventive concept, the backside active contact is formed such that an upper part thereof has a relatively wide width from a point of view of a backside of a transistor, the backside active contact may be relatively easily formed. That is, since the backside active contact having a relatively wide width may be formed before the backside isolation structure, a process margin may be secured and the backside active contact may be more easily manufactured. Accordingly, a cost associated with a manufacturing process of the semiconductor device may be reduced.

Although embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A semiconductor device comprising:
a substrate;
a lower power line disposed under the substrate;
a source/drain pattern on the substrate;
a channel pattern, on side surfaces of the source/drain pattern, including a plurality of semiconductor patterns stacked on each other;
a gate electrode between the plurality of semiconductor patterns;
a backside active contact penetrating the substrate to electrically connect the lower power line and the source/drain pattern; and
a backside isolation structure penetrating the substrate and the backside active contact, and disposed under the gate electrode,
wherein an uppermost surface of the backside active contact is located at a higher level than an uppermost surface of the backside isolation structure.

2. The semiconductor device of claim 1, wherein a bottom surface of the backside isolation structure is substantially coplanar with a bottom surface of the backside active contact.

3. The semiconductor device of claim 1, wherein the backside active contact comprises a backside conductive pattern and a backside barrier pattern on the uppermost surface the backside conductive pattern.

4. The semiconductor device of claim 3, wherein the backside barrier pattern covers sidewalls of the backside conductive pattern.

5. The semiconductor device of claim 3, wherein an upper part of the backside isolation structure is in contact with the substrate, and
a lower part of the backside isolation structure is in contact with the backside active contact.

6. The semiconductor device of claim 5, wherein a first portion of the lower part of the backside isolation structure is in direct contact with the backside barrier pattern, and
a second portion of the lower part of the backside isolation structure is in direct contact with the backside conductive pattern.

7. The semiconductor device of claim 1, wherein the backside isolation structure has a tapered shape from a narrow portion at the gate electrode to a wide portion away from the gate electrode, and
wherein the backside active contact has a tapered shape from a narrow portion at the source/drain pattern to a wide portion away from the source/drain pattern.

8. The semiconductor device of claim 1, further comprising a gate insulating film interposed between the gate electrode and the plurality of semiconductor patterns,
wherein the gate electrode includes a first inner electrode, a second inner electrode, and a third inner electrode interposed between adjacent semiconductor patterns among the plurality of semiconductor patterns, and an outer electrode on an uppermost semiconductor pattern, and
the backside isolation structure is in direct contact with a bottom surface of the gate insulating film surrounding the first inner electrode.

9. The semiconductor device of claim 8, further comprising a gate contact electrically connected to the gate electrode,
wherein the gate contact is in contact with the outer electrode.

10. A semiconductor device comprising:
a substrate;
a plurality of semiconductor patterns, on the substrate, horizontally spaced apart from each other;
source/drain patterns including a first pattern and a second pattern respectively interposed between the plurality of semiconductor patterns;
a gate electrode between the substrate and each of the plurality of semiconductor patterns;
a gate insulating film surrounding the gate electrode;
a backside active contact provided under the substrate, and including a third pattern electrically connected to the first pattern and a fourth pattern separated from the second pattern; and
backside isolation structures penetrating the substrate and the backside active contact,
wherein the backside isolation structures include a first backside isolation structure, a second backside isolation structure, and a third backside isolation structure horizontally spaced apart from each other, and
the third pattern is disposed between the first backside isolation structure and the second backside isolation structure, and the fourth pattern is disposed between the second backside isolation structure and the third backside isolation structure.

11. The semiconductor device of claim 10, wherein the backside active contact comprises a backside conductive pattern and a backside barrier pattern on the backside conductive pattern,
the first backside isolation structure comprises a first part, a second part on the first part, and a third part on the second part,
the first part is in direct contact with the backside conductive pattern,
the second part is in direct contact with the backside barrier pattern, and
the third part is in direct contact with the substrate.

12. The semiconductor device of claim 11, wherein the backside conductive pattern comprises a metal material,
the backside barrier pattern comprises a metal nitride film, and
the metal nitride film comprises at least one of titanium nitride (TiN), tantalum nitride (TaN), tungsten nitride (WN), nickel nitride (NiN), cobalt nitride (CoN), or platinum nitride (PtN).

13. The semiconductor device of claim 10, further comprising a metal-semiconductor compound layer between the first pattern and the third pattern.

14. The semiconductor device of claim 10, wherein an uppermost surface of the third pattern is located at a first level,
an uppermost surface of the fourth pattern is located at a second level,
an uppermost surface of each of the backside isolation structures is located at a third level, and
the third level is higher than the second level, and lower than the first level.

15. The semiconductor device of claim 10, wherein an uppermost surface of the third pattern is higher than or equal to a level of an upper surface of the gate insulating film.

16. The semiconductor device of claim 10, wherein the fourth pattern is disposed on a lower surface of the substrate.

17. The semiconductor device of claim 10, wherein the backside isolation structures are disposed on a bottom surface of the gate insulating film.

18. The semiconductor device of claim 10, wherein a width of each of the backside isolation structures is tapered toward a vertical direction of the substrate.

19. A semiconductor device comprising:
a substrate including an active pattern;
a device isolation film on the substrate and defining the active pattern;
a channel pattern and source/drain patterns on the active pattern, the source/drain patterns including a first source/drain pattern and a second source/drain pattern horizontally spaced apart from each other;
a gate electrode on the channel pattern;
a gate insulating film interposed between the gate electrode and the channel pattern;
a gate spacer on sidewalls of the gate electrode;
a gate capping pattern on an upper surface of the gate electrode;
an interlayer insulating film covering the source/drain patterns and the gate capping pattern;
an upper active contact penetrating the interlayer insulating film to be electrically connected to the first source/drain pattern;
a metal-semiconductor compound layer interposed between the upper active contact and the first source/drain pattern;
a gate contact penetrating the interlayer insulating film and the gate capping pattern to be electrically connected to the gate electrode;
a lower power line provided under the substrate;
a backside active contact penetrating the substrate to electrically connect the lower power line and the second source/drain pattern; and
a backside isolation structure penetrating the substrate and the backside active contact, and disposed on the gate insulating film,
wherein a bottom surface of the backside isolation structure is coplanar with a bottom surface of the backside active contact and an upper surface of the lower power line, and
an upper surface of the backside isolation structure is in contact with a bottom surface of the gate insulating film.

20. The semiconductor device of claim 19, further comprising:
a first metal layer, on the interlayer insulating film, including a first line electrically connected to the gate contact; and
a second metal layer, on the first metal layer, including a second line electrically connected to the first metal layer, and
wherein the backside isolation structure comprises:
a first part including a first side surface;
a second part, on the first part, including a second side surface; and
a third part on the second part, including a third side surface,
the first side surface is in direct contact with a backside conductive pattern of the backside active contact,
the second side surface is in direct contact with a backside barrier pattern of the backside active contact, and
the third side surface is in direct contact with the substrate.
